(19) United States
(12) Patent Application Publication
(10) Pub. No.: US 2014/0104284 A1
(43) Pub. Date: Apr. 17, 2014

(54) THROUGH SUBSTRATE VIA INDUCTORS

(71) Applicant: QUALCOMM MEMS TECHNOLOGIES, INC., San Diego, CA (US)

(72) Inventors: Ravindra V. Shenoy, Dublin, CA (US); Jitae Kim, Mountain View, CA (US); Kwan-yu Lai, San Jose, CA (US); Jon Bradley Lasiter, Stockton, CA (US); Philip Jason Stephanou, Mountain View, CA (US); Donald William Kidwell, Los Gatos, CA (US); Evgeni Petrovich Gousev, San Jose, CA (US)

(73) Assignee: QUALCOMM MEMS TECHNOLOGIES, INC., San Diego, CA (US)

(21) Appl. No.: 13/653,132

(22) Filed: Oct. 16, 2012

(51) Int. Cl. H01F 27/28; H01K 3/10; G06T 1/00; H03H 7/01; G01B 7/16

(52) U.S. Cl. 345/501; 336/200; 333/176; 73/779; 29/852

(57) ABSTRACT

This disclosure provides systems, methods, and apparatus for through substrate via inductors. In one aspect, a cavity is defined in a glass substrate. At least two metal bars are in the cavity. A first end of each metal bar is proximate a first surface of the substrate, and a second end of each metal bar is proximate a second surface of the substrate. A metal trace connects a first metal bar and a second metal bar. In some instances, one or more dielectric layers can be disposed on surfaces of the substrate. In some instances, the metal bars and the metal trace define an inductor. The inductor can have a degree of flexibility corresponding to a variable inductance. Metal turns can be arranged in a solenoidal or toroidal configuration. The toroidal inductor can have tapered traces and/or thermal ground planes. Transformers and resonator circuitry can be realized.

### TECHNICAL FIELD

This disclosure relates generally to inductors and more particularly to through substrate via inductors.

### DESCRIPTION OF THE RELATED TECHNOLOGY

Electromechanical systems (EMS) include devices having electrical and mechanical elements, transducers such as sensors and actuators, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

Inductors are ubiquitous passive analog electronic components that are used in a myriad of power regulation, frequency control, and signal conditioning applications in a range of devices including personal computers, tablet computers, and wireless mobile handsets. Real inductors have a finite quality factor (Q), meaning that in addition to storing energy in an induced magnetic field, they also dissipate energy through ohmic and magnetic losses. Moreover, inductors may require large physical dimensions (on the order of millimeters) in order to achieve inductance values greater than tens of nanohenries (nH). Some inductors are fabricated with cores made of a high magnetic permeability material, which increases their inductance density. Due to challenges associated with designing and fabricating inductors with the requisite form factor, quality factor, and inductance density, inductors are often discrete components that are integrated with other discrete and integrated electronic elements at the board level.

### SUMMARY

The systems, methods and devices of this disclosure each have several innovative aspects, no single one of which is solely responsible for the desirable attributes disclosed herein.

One innovative aspect of the subject matter described in this disclosure can be implemented in a device including an insulating substrate such as a glass substrate with a cavity defined in the substrate. At least two metal bars are in the cavity. A first end of each metal bar is proximate a first surface of the substrate, and a second end of each metal bar is proximate a second surface of the substrate. A metal trace connects a first metal bar and a second metal bar.

In some implementations, a first dielectric layer can be disposed on the first surface of the substrate, and a second dielectric layer can be disposed on the second surface of the substrate. In such implementations, the cavity is further defined in the first and the second dielectric layers. The metal trace can be in contact with the first dielectric layer. Also, the substrate can include a photoimageable glass substrate. In some implementations, the metal bars can include one or more solid metal bars and/or one or more hollow metal bars. In some implementations, a magnetic core can be disposed in the cavity. The first metal bar, the second metal bar, and the metal trace can define borders with respect to the magnetic core. In some implementations, resonator circuitry can be realized by connecting a capacitor in a circuit with the device.

In some implementations, the metal bars and the metal trace define at least part of an inductor. The inductor can have a degree of flexibility corresponding to a variable inductance of the inductor. In some implementations, the metal bars and the metal trace define at least a portion of one of a plurality of metal turns arranged in a toroid to define a toroidal inductor situated in a plane substantially parallel to the substrate. In some implementations of a toroidal inductor, the metal trace can have a tapered shape along the plane, where the tapered shape is defined by a wider portion proximate an outer side of the toroid and a narrower portion proximate an inner side of the toroid. The toroid can have a circular shape, an elliptical shape, a racetrack shape, or some combination thereof.

In some implementations of a toroidal inductor, one or more thermal ground planes can be disposed on one or both surfaces of the substrate, where the cavity is further defined in the one or more thermal ground planes. A thermal ground plane can include a material such as aluminum nitride (AlN), diamond-like carbon (DLC), or graphene.

In some implementations where the metal bars and the metal trace define at least part of a toroidal inductor, the metal turns of the inductor include a first set of turns defining a first coil having an input terminal and an output terminal, and a second set of turns defining a second coil having an input terminal and an output terminal. In such instances, the first coil and the second coil can define a transformer. In some instances, at least a portion of the first coil overlays the second coil. In some other instances, the first coil is situated in a first portion of the toroid, and the second coil is situated in a second portion of the toroid and spaced apart from the first coil.

Another innovative aspect of the subject matter described in this disclosure can be implemented in a method in which at least two vias are formed in a glass substrate. An area of the glass substrate where a cavity is to be formed includes the vias. The glass substrate is exposed to an elevated temperature. A metal layer is deposited, and the metal layer at least partially fills a first via and a second via. A trace connecting metals of the first via and the second via is formed.

In some implementations, the area of the glass substrate where the cavity is to be formed can be exposed to ultraviolet light, and this area can be etched with an acid. In some implementations, forming the vias in the glass substrate can include exposing the area of the glass substrate where the vias are to be formed to the ultraviolet light, exposing the glass substrate to the elevated temperature, and etching the vias in the glass substrate with the acid. In some other implementations, forming the vias in the glass substrate can include a sandblasting process, a laser ablation process, an ultrasonic drilling process and/or an acid etch process. In some implementations, depositing the metal layer can include depositing a seed layer by physical vapor deposition, chemical vapor deposition, evaporation, atomic layer deposition, and/or electroless plating, and plating a metal on the seed layer. In some implementations, a dielectric adhesion layer can be deposited such that the metal layer is deposited on the dielectric adhesion layer.

In some implementations, a dielectric layer is deposited on a first side and on a second side of the glass substrate. In some implementations, a portion of the dielectric layer disposed on the first side of the glass substrate can be removed to uncover at least a portion of the area of the glass substrate. In some implementations, a thermal ground plane layer can be deposited on one or more of the first side and the second side of the glass substrate.

Another innovative aspect of the subject matter described in this disclosure can be implemented in a method in which at least two vias are formed with a channel between the vias in a glass substrate. An area of the glass substrate where a cavity is to be formed includes the vias and the channel. The glass substrate is exposed to an elevated temperature. A first polymer support is formed in a portion of the channel. A magnetic core is formed in the channel, and the magnetic core is disposed on the first polymer support. A second polymer support is formed in the channel, and the second polymer support is disposed on the magnetic core. A metal layer is deposited, and the metal layer at least partially fills a first via and a second via. A trace connecting metals of the first via and the second via is formed.

In some implementations, a dielectric layer is deposited on a first side and on a second side of the glass substrate. In some implementations, a thermal ground plane layer is deposited on one or more of a first side and a second side of the glass substrate. In some implementations, forming the first polymer support and the second polymer support can include depositing a polymer material, removing portions of the polymer material not overlying the channel, and heating the polymer material such that the polymer material flows into the channel.

One innovative aspect of the subject matter described in this disclosure can be implemented in a device including a substrate where at least a portion of the substrate includes an insulating material such as a glass. A cavity and at least two vias are defined in the substrate. A metal is disposed in the vias. A metal trace connects the metal disposed in a first via and the metal disposed in a second via. The metal trace is disposed over a surface of the substrate. The metal disposed in the first via, the metal disposed in the second via, and the metal trace define borders with respect to the cavity.

In some implementations, a magnetic core can be disposed in the cavity. The magnetic core can include a bulk or sintered ferromagnetic or ferrimagnetic material, or particles of a ferromagnetic or ferrimagnetic material in a polymer matrix. In some instances, a section of the substrate protrudes into the cavity. When a magnetic core is disposed in the cavity, the section of the substrate can protrude into the magnetic core. In some implementations, the substrate includes a bottom glass substrate and a top glass substrate. When a magnetic core is disposed in the cavity, an adhesive can bind the magnetic core to a surface of the cavity. In some other implementations, the substrate includes a bottom glass substrate, a cavity substrate, and a top glass substrate. The cavity substrate can include an open region defining the cavity when the bottom glass substrate is disposed on a bottom surface of the cavity substrate. The top glass substrate can be disposed on a top surface of the cavity substrate. By way of example, the cavity substrate can include a glass cavity substrate, and a photoimageable glass cavity substrate.

In some implementations, the metal trace and the metal disposed in the first and second vias define at least part of an inductor, such as a toroidal inductor having some or all of the characteristics described above. As mentioned above, the inductor can have a degree of flexibility corresponding to a variable inductance of the inductor. In some implementations, the inductor can be configured to provide an output signal at an output terminal responsive to a strain or displacement of the flexible substrate.

Another innovative aspect of the subject matter described in this disclosure can be implemented in a method in which a concave recess is formed in each of a bottom glass substrate and a top glass substrate. The bottom glass substrate is attached to the top glass substrate to form a composite substrate. The concave recesses in each substrate define a cavity in the composite substrate. At least two vias are formed in the composite substrate. A metal layer is deposited. The metal layer at least partially fills a first via and a second via and forms a trace connecting metals of the first via and the second via. The first via, the second via, and the trace define borders with respect to the cavity.

In some implementations, the bottom glass substrate and the top glass substrate include a photoimageable glass. Also, forming the vias in the composite substrate can include exposing an area of the composite substrate where the vias are to be formed to ultraviolet light, exposing the composite substrate to an elevated temperature, and etching the vias in the composite substrate with an acid. In some other implementations, forming the vias in the glass substrate can include a media blasting process, a laser ablation process, an ultrasonic drilling process, and/or an acid etch process. In some implementations, depositing the metal layer can include depositing a seed layer by physical vapor deposition, chemical vapor deposition, evaporation, atomic layer deposition, and/or electroless plating, and electroplating a metal on the seed layer. In some implementations, a magnetic core can be attached to the concave recess of the top glass substrate or the bottom glass substrate before attaching these substrates. In some implementations, a material including a bulk ferromagnetic or ferrimagnetic material, or a polymer and particles of a ferromagnetic material or a ferrimagnetic material can be deposited in the concave recess of the bottom glass substrate and/or the top glass substrate before attaching these substrates, and the polymer can be cured. In some instances, a section of the bottom glass substrate and/or the top glass substrate protrudes into the concave recess. In some instances, the particles can be sintered. In some instances, the ferromagnetic material or the ferrimagnetic material can be electroplated.

Another innovative aspect of the subject matter described in this disclosure can be implemented in a method in which an open region is formed in a cavity substrate. A bottom glass substrate is attached to a bottom surface of the cavity substrate. A top glass substrate is attached to a top surface of the cavity substrate. The bottom glass substrate, the cavity substrate, and the top glass substrate form a composite substrate defining a cavity. At least two vias are formed in the composite substrate. A metal layer is deposited. The metal layer at least partially fills a first via and a second via and forms a trace connecting metals of the first via and the second via.

In some implementations, the first via, the second via, and the trace define borders with respect to the cavity. In some implementations, the bottom glass substrate, the cavity substrate, and the top glass substrate can include a photoimageable glass. Also, forming the vias in the composite substrate can include exposing an area of the composite substrate where the vias are to be formed to ultraviolet light, exposing the composite substrate to an elevated temperature, and etching the vias in the composite substrate with an acid. In some implementations, forming the vias in the glass substrate can include a sandblasting process, a laser ablation process, and/or an acid etch process. Also, in some implementations, a thermal ground plane layer can be deposited on a first side and/or a second side of the composite substrate.

In some implementations, a magnetic core can be attached to a recessed portion formed after attaching the bottom glass substrate to the bottom surface of the cavity substrate. In some implementations, a bulk ferromagnetic or ferrimagnetic material, or a material including a polymer and particles of a ferromagnetic material or a ferrimagnetic material can be deposited in a recess formed after attaching the bottom glass substrate to the bottom surface of the cavity substrate, and the polymer can be cured. In some instances, a section of the cavity substrate protrudes into the recess. In some instances, the particles can be sintered. In some instances, the ferromagnetic material or the ferromagnetic material can be electroplated.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A is an example of a flow diagram illustrating a manufacturing process for a through glass via inductor including an air core.

FIG. 1B is another example of a flow diagram illustrating a manufacturing process for a through glass via inductor including an air core.

FIGS. 2A-2E are examples of schematic illustrations of a through glass via inductor including an air core at various stages in the manufacturing process.

FIG. 3 is an example of an isometric projection of a through glass via inductor including an air core.

FIG. 4 is an example of a flow diagram illustrating a manufacturing process for a through glass via inductor including a magnetic core.

FIGS. 5A-5H are examples of schematic illustrations of a through glass via inductor including a magnetic core at various stages in the manufacturing process.

FIG. 6 is an example of an isometric projection of a through glass via inductor including a magnetic core.

FIG. 7 is an example of a flow diagram illustrating a manufacturing process for a through glass via inductor including two substrates.

FIGS. 8A-8E are examples of schematic illustrations of a through glass via inductor including two substrates at various stages in the manufacturing process.

FIGS. 9A and 9B are examples of schematic illustrations of portions of through glass via inductors.

FIGS. 10A-10F are examples of schematic illustrations of a different manufacturing process for forming a magnetic core for a through glass via inductor.

FIGS. 11A and 11B are examples of top-down schematic illustrations of bottom substrates of through glass via inductors having a toroidal configuration.

FIG. 12 is an example of a flow diagram illustrating a manufacturing process for a through glass via inductor including three substrates.

FIGS. 13A-13F are examples of schematic illustrations of a through glass via inductor including three substrates at various stages in the manufacturing process.

FIGS. 14A-14F are examples of schematic illustrations of a different manufacturing process for forming a magnetic core for a through glass via inductor.

FIGS. 15A and 15B are examples of top-down schematic illustrations of cavity substrates having an attached bottom glass substrate of through glass via inductors having a toroidal configuration.

FIGS. 16A and 16B are examples of top-down schematic illustrations of toroidal through glass via inductors fabricated using any of the processes disclosed herein.

FIG. 16C is an example of a top-down schematic illustration of a toroidal through glass via inductor having tapered metal traces and fabricated using any of the processes disclosed herein.

FIGS. 16D-16F are examples of simplified top-down schematic illustrations of general shapes of toroidal through glass via inductors fabricated using any of the processes disclosed herein.

FIG. 16G is an example of a cross-sectional schematic illustration of a through glass via inductor including one or more thermal ground planes (TGPs) fabricated using any of the processes disclosed herein.

FIGS. 16H and 16I are examples of top-down schematic illustrations of four-terminal toroidal through glass via transformers fabricated using any of the processes disclosed herein.

FIG. 17A is an isometric view illustration depicting two adjacent interferometric modulator (IMOD) display elements in a series or array of display elements of an IMOD display device.

FIG. 17B is a system block diagram illustrating an electronic device incorporating an IMOD-based display including a three element by three element array of IMOD display elements.

FIGS. 18A and 18B are schematic exploded partial perspective views of a portion of an electromechanical systems (EMS) package including an array of EMS elements and a backplate.

FIGS. 19A and 19B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, automotive displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to designs of and fabrication processes for integrated, three-dimensional, EMS and MEMS inductors. The inductors may be fabricated utilizing insulating substrates such as glass substrates and include a cavity that may serve to increase the quality factor of the inductor and/or increase the self-resonant frequency of the inductor. While glass substrates are often described in the examples herein, it is be understood that the innovative aspects of this disclosure are not so limited and are applicable to other types of substrates including other types of rigid and/or insulating substrates. In some implementations, the inductors may include a magnetic core disposed in the cavity that may increase the inductance of the inductor. In some implementations, the cavity may have a rectangular, cylindrical, or other rod-like shape cross section. In some implementations, the inductor may have a solenoid configuration or a toroid configuration.

For example, in some implementations, an inductor may be formed using a glass substrate with an open region. A first dielectric layer may be disposed on a first surface of the glass substrate, and a second dielectric layer may be disposed on a second surface of the glass substrate. The first and the second dielectric layers and the open region of the glass substrate may define a cavity. At least two metal bars may be situated in the cavity. A first end of each metal bar may be proximate the first dielectric layer, and a second end of each metal bar may be proximate the second dielectric layer. A metal trace may connect a first end of a first metal bar and a first end of a second metal bar, the metal trace being in contact with the first dielectric layer. A magnetic core of the inductor can be disposed in the cavity. In forming the inductor, in some implementations, two or more vias are formed in the substrate. A metal layer can be deposited, such that the metal layer at least partially fills the vias and forms the metal trace. In some instances, the vias are formed by exposing an area of the substrate to ultraviolet light, exposing the substrate to an elevated temperature, and etching the vias in the substrate with an acid.

For example, in some other implementations, an inductor may include a substrate, at least a portion of which includes a glass. The substrate may define a cavity and two or more vias. A metal may be disposed in the vias. A metal trace may connect the metal disposed in a first via and the metal disposed in a second via. The metal trace may be disposed on a surface of the substrate. The metal disposed in the first via and the second via and the metal trace may be proximate the borders with respect to the cavity. A magnetic core of the inductor can be disposed in the cavity and can include a bulk ferromagnetic or ferrimagnetic material, or particles of a ferromagnetic material or a ferrimagnetic material. In some implementations, the substrate includes two or more insulating substrates, such as a bottom glass substrate, a top glass substrate, and additional substrates as desired. In forming the inductor, in some implementations, two or more vias are formed in the substrate. A metal layer can be deposited, such that the metal layer at least partially fills the vias and forms the metal trace. In some instances, the vias are formed by exposing an area of the substrate to ultraviolet light, exposing the substrate to an elevated temperature, and etching the vias in the substrate with an acid.

Particular implementations of the subject matter described in this disclosure can be implemented to realize one or more of the following potential advantages. Compared to discrete inductors, in some implementations, an inductor as described herein may have a reduced form factor. For example, the inductor as described herein notably may have a reduced height or lateral area as compared to discrete inductors. The fabrication processes for the inductor may allow for co-fabrication with other MEMS devices and semiconductor devices such as thin film transistors and have a reduced cost. In some examples of the disclosed inductors having a cavity with no magnetic core, when the substrate is removed, inter-winding capacitance can be reduced, which can increase the self-resonant frequency of the inductor.

Compared to integrated MEMS inductors, in some implementations, an inductor as described herein may have a greater cross-sectional area for the magnetic flux path for higher inductance, a thicker magnetic core for improved linearity, thicker conductor traces for higher quality factor, and enable the use of a variety of magnetic core materials, including ones that are not available in a thin-film configuration. With some examples of the disclosed magnetic core inductors, the presence of a high permeability magnetic core tends to concentrate magnetic flux within the inductor windings, serving to decrease parasitic inter-device coupling. Compared to magnetic core materials that are available in thin film configurations, in some implementations, an inductor as described herein may incorporate magnetic core materials having a lower magnetic loss tangent, a higher magnetic roll-off frequency, and a lower electrical conductivity. Moreover, the magnetic core materials can have a higher quality factor and higher permeability for higher inductance density. In some implementations, the fabrication processes also provide a customizable magnetic core cross-sectional area based on the thickness of the substrate. Thus, the inductor can have various dimensions.

In some instances, inductors having toroidal shapes as disclosed herein may have an even higher inductance density and higher quality factor than other three-dimensional inductors. The disclosed toroidal inductors can be integrated with other passive components such as solenoidal and planar spiral inductors, metal-insulator-metal (MIM) capacitors, thin film resistors, and with active components such as thin film transistors (TFTs). These various components can be co-fabricated due to compatibility of the disclosed processes. Such components can be integrated in various combinations to realize devices such as resonant LC tanks, e.g., for clock references, bandpass filters, and notch filters, as well as to realize impedance matching networks, power transformers, power combiners, and other systems.

In some applications of the disclosed techniques, batch fabrication of toroidal inductors with other components on glass substrates is amenable to low per-unit cost. Form factors less than 1 millimeter in thickness are possible to meet specifications of modern mobile handsets and other modern consumer electronic devices and systems including tablets and laptop computers. In addition, the toroidal topology of some examples of the disclosed inductors can minimize stray magnetic fields around inductors. Any cross-talk between components and/or mutual inductance of inductors in close proximity to each other can be reduced. This reduction, in turn, enables denser integration of passive components and integrated circuits, for example, including three-dimensional stacked die architectures. In addition, magnetic flux can be effectively confined within a toroidal inductor for reduced parasitic coupling.

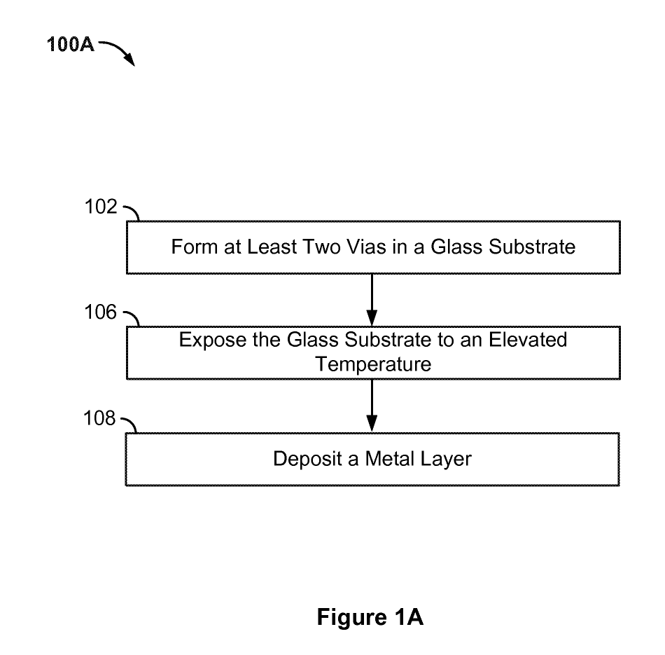

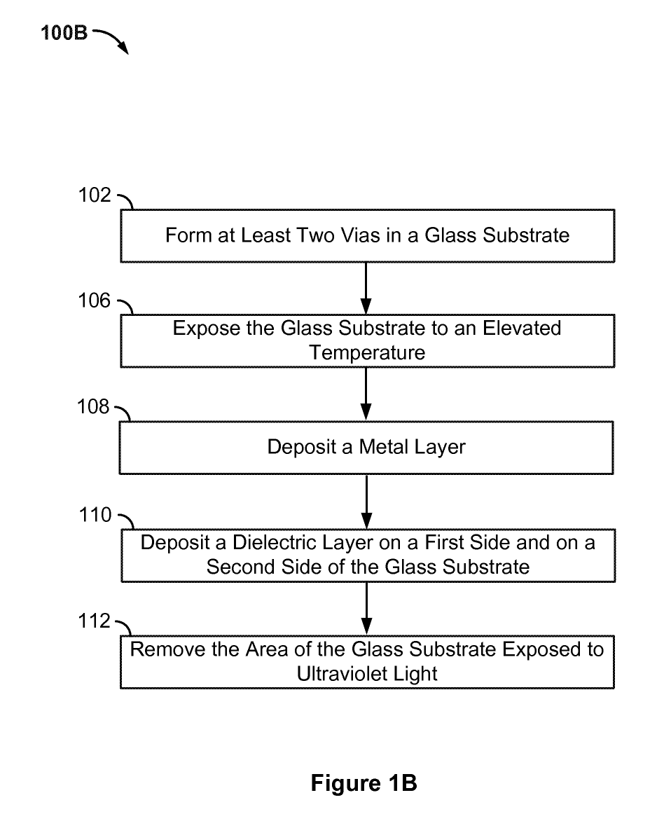

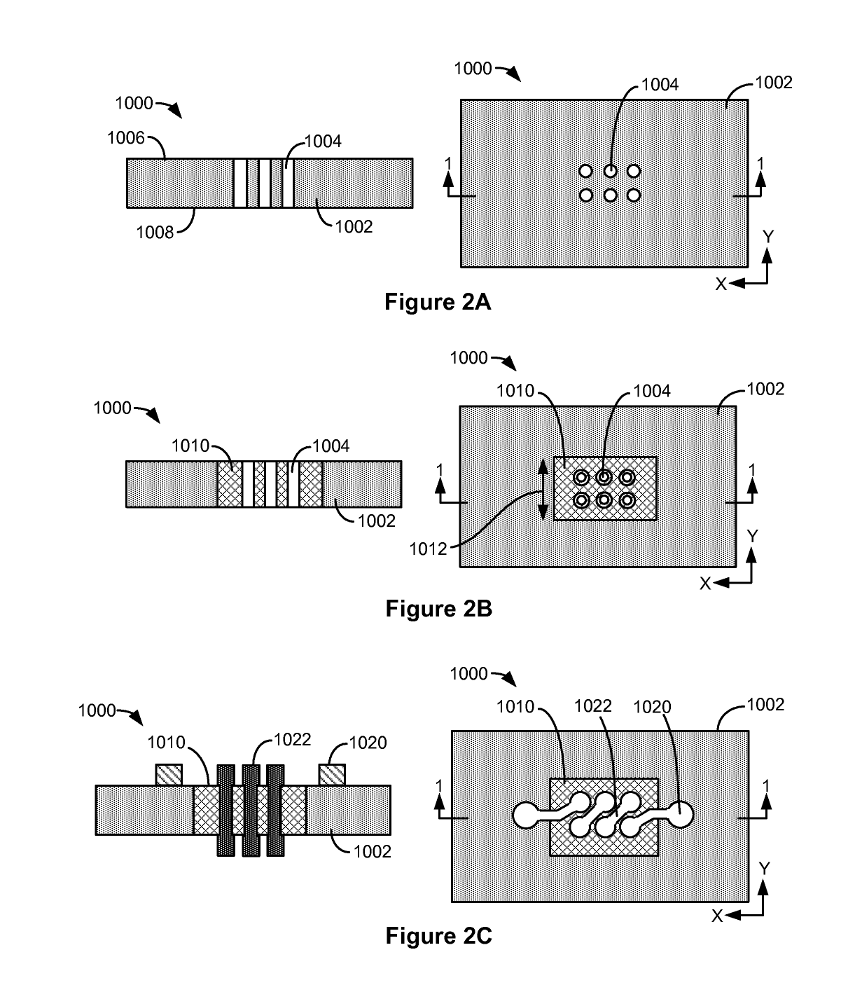

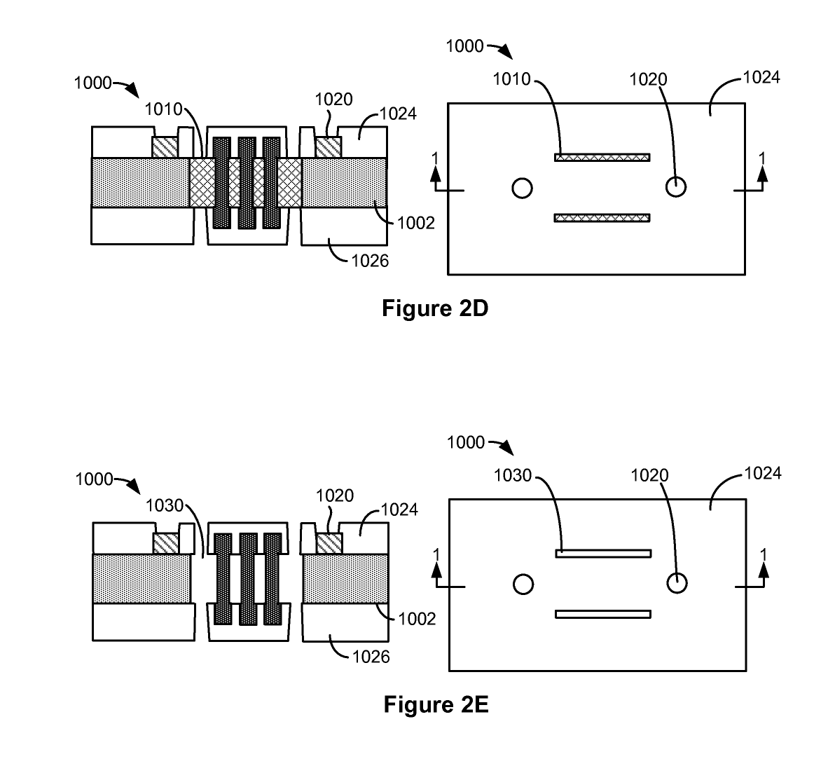

To aid in the understanding of implementations of through glass via inductors as described herein, implementations of manufacturing processes for an inductor, accompanied by top-down and cross-sectional schematic illustrations of an inductor at various stages in the manufacturing process, are set forth below. FIG. 1A is an example of a flow diagram illustrating a manufacturing process for a through glass via inductor including an air core. FIGS. 2A-2C are examples of schematic illustrations of a through glass via inductor including an air core at various stages in the manufacturing process of FIG. 1A. FIG. 1B is another example of a flow diagram illustrating a manufacturing process for a through glass via inductor including an air core. FIGS. 2A-2E are examples of schematic illustrations of a through glass via inductor including an air core at various stages in the manufacturing process of FIG. 1B. Each of FIGS. 2A-2E includes an example of a cross-sectional schematic illustration of the inductor through line 1-1 in the corresponding top-down schematic illustration.

In a process 100A shown in FIG. 1A, patterning techniques, including masking as well as etching processes, may be used to define the shapes of the different components of an inductor. At block 102 of the process 100A, at least two vias are formed in a glass substrate. In some implementations, the glass substrate may include a photoimageable glass. One example of photoimageable glass is APEX™ Glass, manufactured by Life Bioscience, Inc. (Albuquerque, N. Mex.), although other photoimageable glass manufacturers also can supply the requisite substrates. Photoimageable glasses are generally borosilicate-based glasses with oxide additions.

Different processes may be used to form the vias in the glass substrate. For example, a laser ablation process, a mediablasting process, an ultrasonic drilling process, or an etching process (e.g., a chemical wet etching process or a dry reactive ion etching process), or a combination of the above processes, may be used to form the vias. In some implementations, the vias may be formed by exposing a photoimageable glass where the vias are to be formed to ultraviolet (UV) light. A mask, for example, may be used to define the area of the photoimageable glass that is exposed to ultraviolet light. The photoimageable glass may then be exposed to an elevated temperature. Exposing an area of the photoimageable glass to ultraviolet light and then exposing the photoimageable glass to an elevated temperature may result in a change of the structural and/or chemical properties of the area exposed to ultraviolet light. As a result, this exposed area may have a higher etch rate than the unexposed area of the photoimageable glass, allowing the vias to be etched in the photoimageable glass using an acid (e.g., hydrofluoric acid (HF)).

FIG. 2A shows examples of schematic illustrations of the partially fabricated inductor at this point (e.g., up through block 102) in the process 100A. An inductor 1000 includes a glass substrate 1002 defining at least two vias, one via of which is a via 1004. In some implementations, the photoimageable glass substrate 1002 may have a thickness in the range of about 30 microns (um) to about 1 millimeter (mm), such as a thickness of about 300 microns. In some implementations, the vias may have a diameter in the range of about 20 microns to about 500 microns.

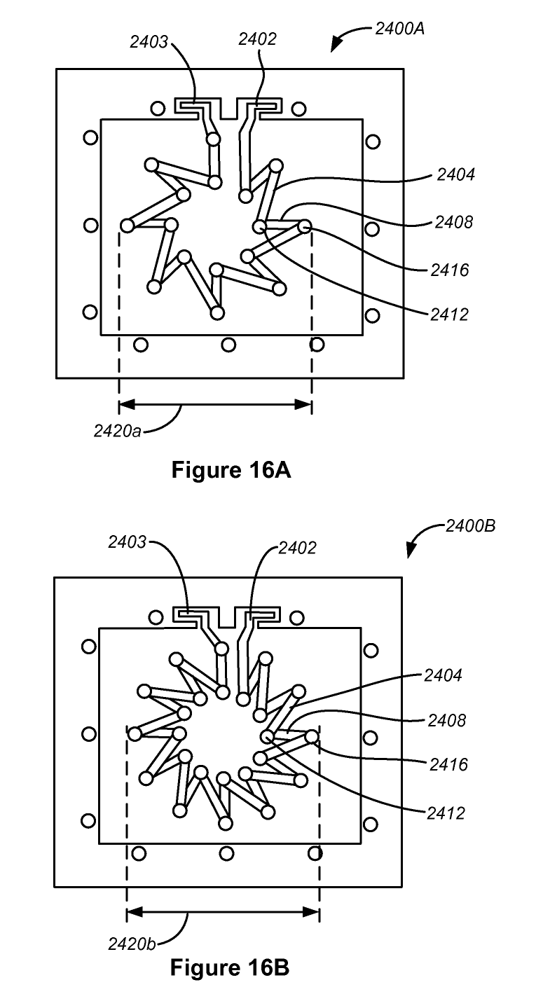

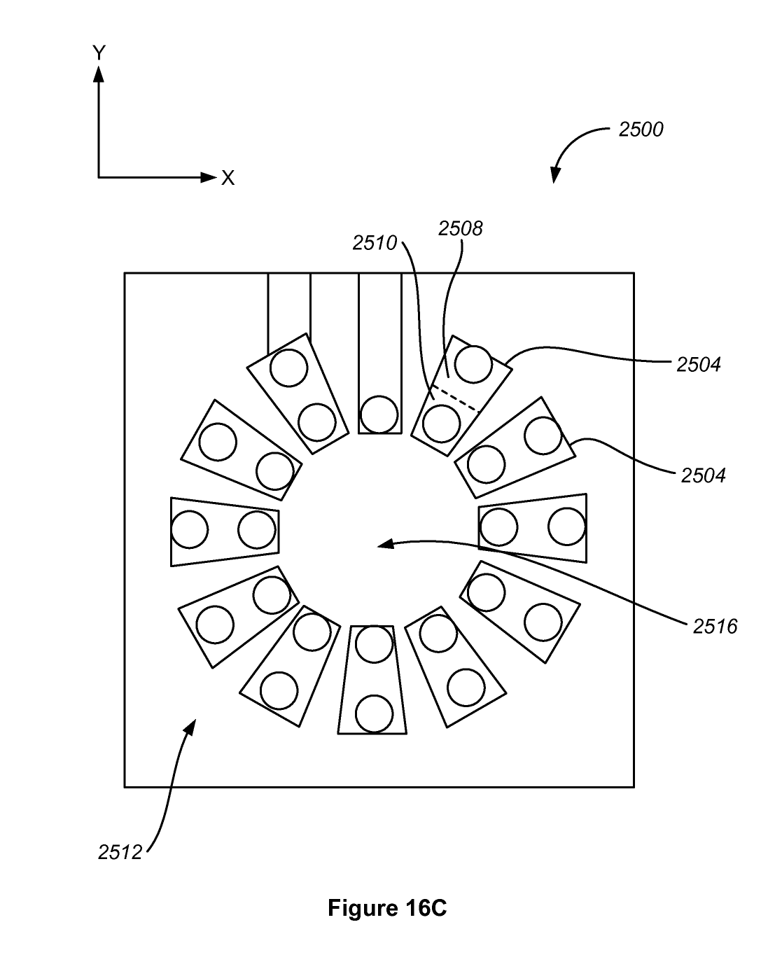

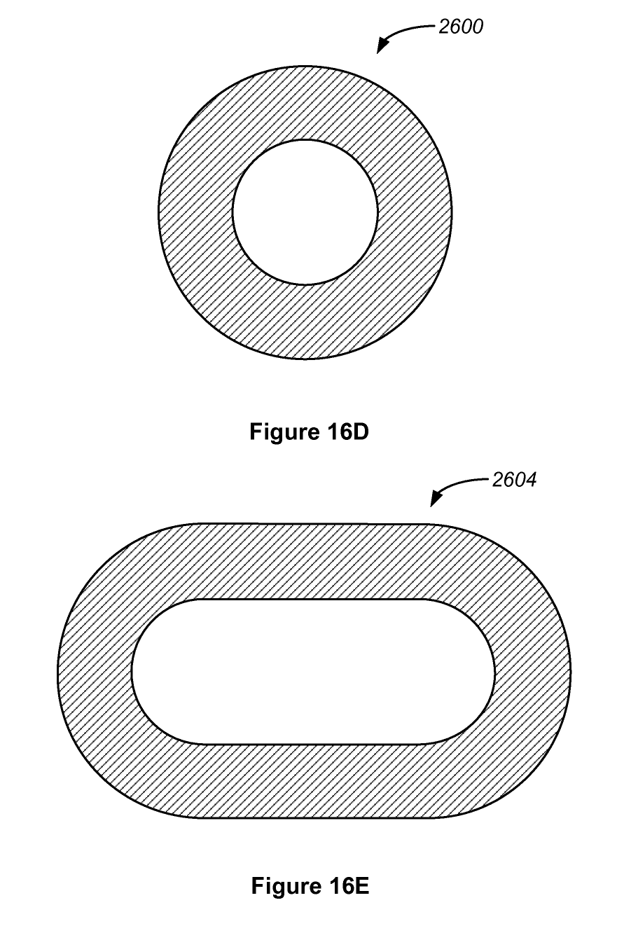

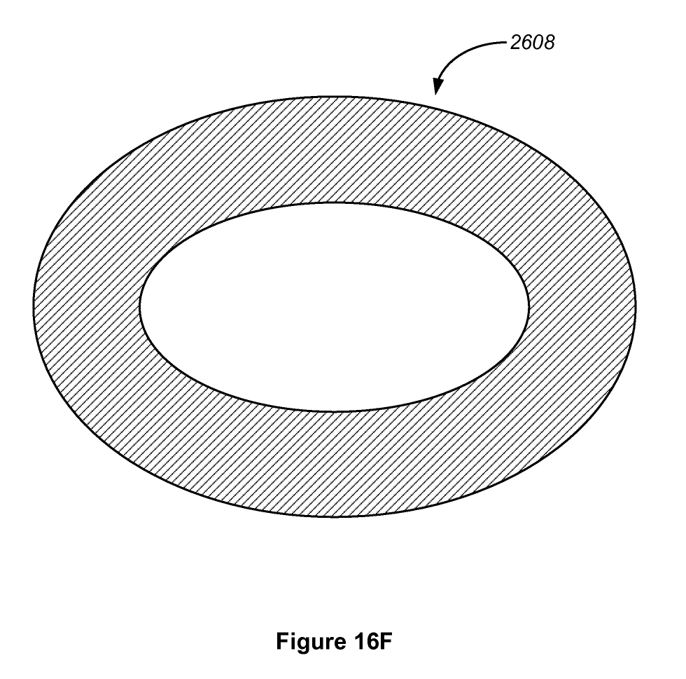

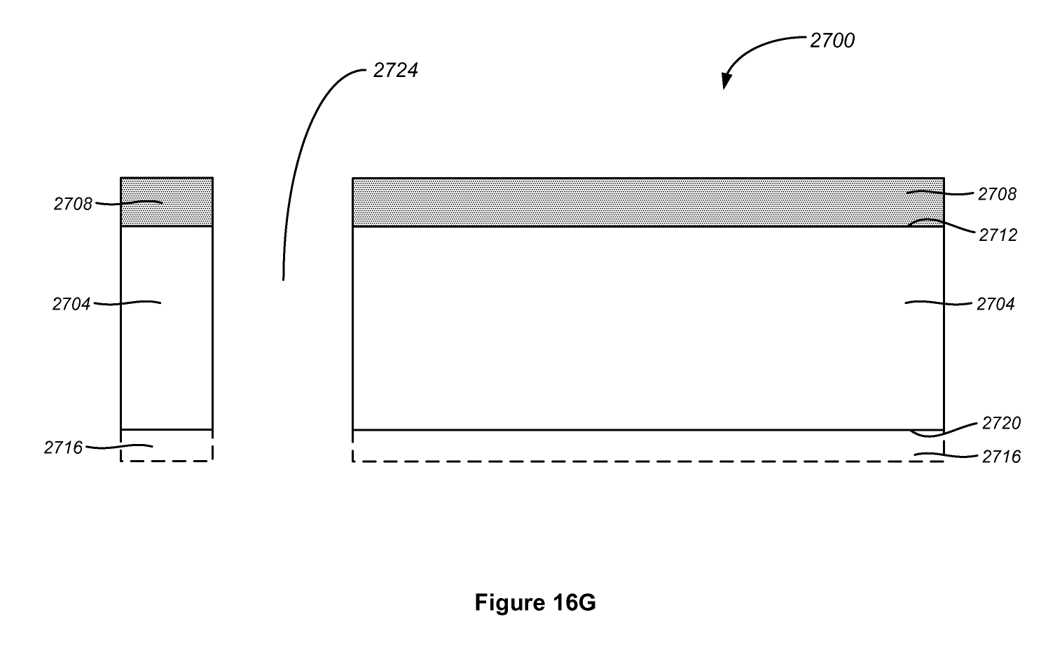

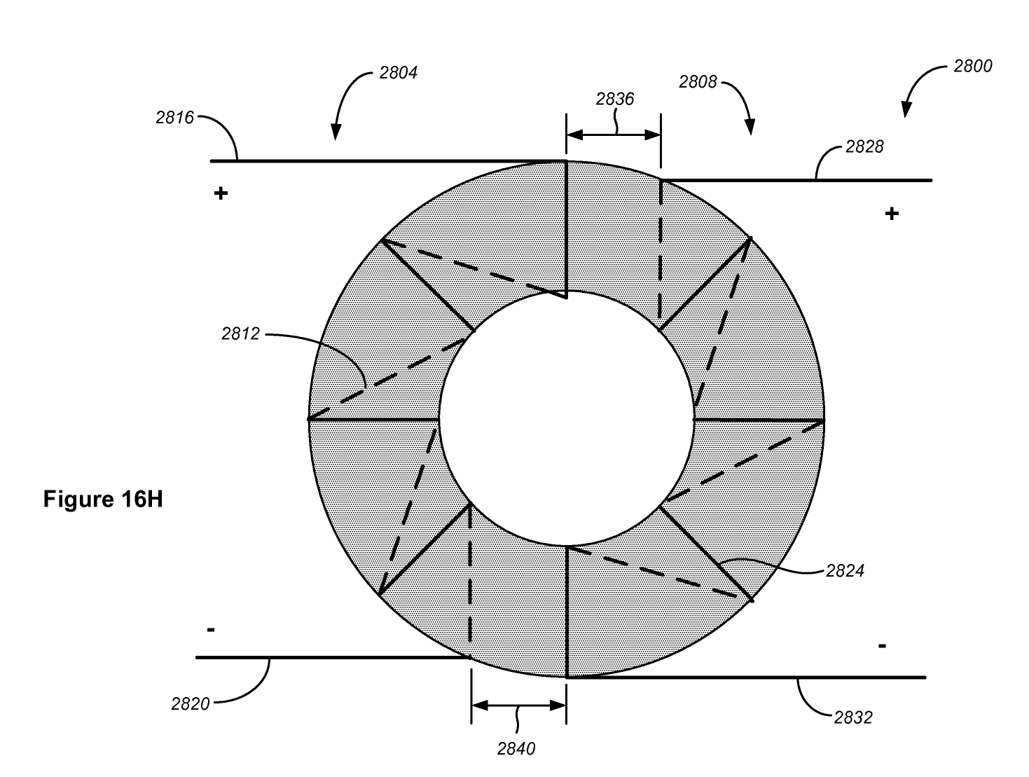

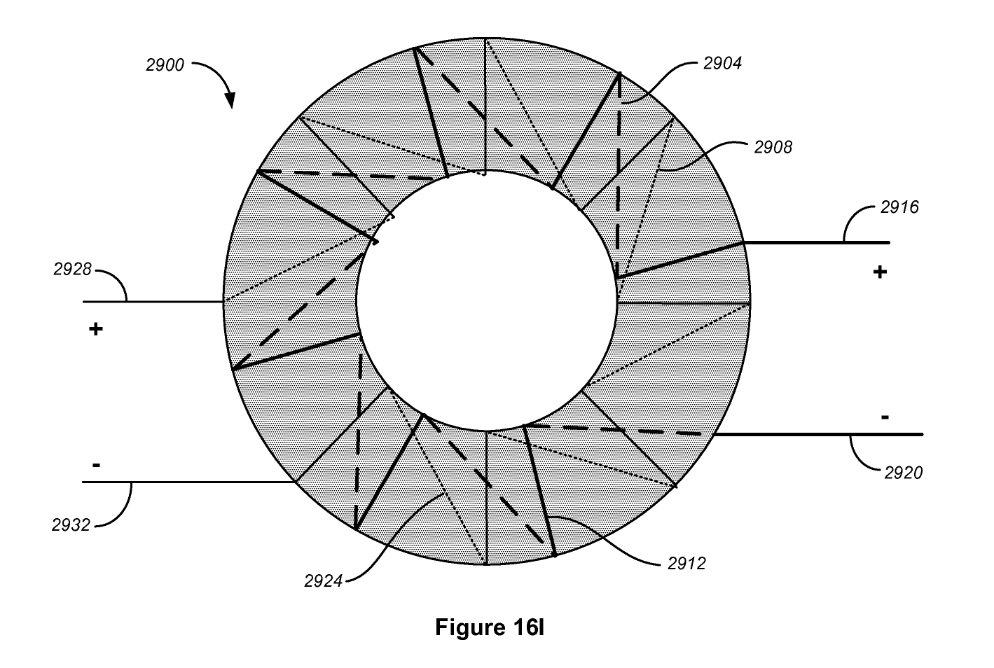

In FIG. 2A, in some implementations, an upper surface 1006 and/or a lower surface 1008 of the glass substrate 1002 may be coated with a thermal ground plane (TGP) including a material such as aluminum nitride (AlN) before forming the vias in both the substrate 1002 and TGP layer(s) at block 102, as described in greater detail below with respect to FIG. 16G. For example, AlN can be sputter-deposited on one or both sides of the glass substrate 1002 before performing additional processing blocks as described herein.

Returning to FIG. 1A, an area of the glass substrate where a cavity is to be formed can be exposed to ultraviolet light. In some implementations, the area where the cavity is to be formed includes the at least two vias formed in operation 102. At block 106, the glass substrate is exposed to an elevated temperature. Exposing an area of a photoimageable glass to ultraviolet light and then exposing the photoimageable glass to an elevated temperature may result in a change of the structural and/or chemical properties of the area exposed to ultraviolet light. As a result, this exposed area may have a higher etch rate than the unexposed area of the photoimageable glass.

FIG. 2B shows examples of schematic illustrations of the partially fabricated inductor 1000 at this point (e.g., up through block 106) in the process 100A. The inductor 1000 includes the glass substrate 1002 defining at least two vias, one via of which is the via 1004. Area 1010 is the area of the glass substrate 1002 exposed to ultraviolet light. The area 1010 may have a width 1012 of about 100 microns to a few millimeters.

Returning to FIG. 1A, at block 108 a metal layer is deposited. In some implementations, the deposited metal layer at least partially fills the vias and forms traces connecting the vias. For example, when two vias are present, a trace may connect the metal of a first via with the metal of a second via.

In some implementations, a dry film mask may be used to define the regions of the glass substrate onto which the metal layer is deposited. In some implementations, the dry film mask may be made of a photo-sensitive polymer. In some implementations, the metal layer may be deposited using a physical vapor deposition (PVD) process, a chemical vapor deposition (CVD) process, an evaporation process, an electroless plating process, or combination of such processes.

In some other implementations, the metal layer may be deposited using a plating process. For example, a seed layer may first be deposited onto surfaces of the glass substrate. In some implementations, the seed layer may be deposited using a PVD process, a CVD process, an evaporation process, an atomic layer deposition (ALD) process, or an electroless plating process. In some implementations, the seed layer may include titanium (Ti), titanium nitride (TiN), ruthenium-titanium nitride (Ru—TiN), platinum (Pt), palladium (Pd), gold (Au), silver (Ag), copper (Cu), nickel (Ni), Mo, or tungsten (W). In some implementations, the seed layer may be about 25 nanometers (nm) to 500 nm thick. After the seed layer is deposited, the metal layer may be deposited using a plating process, with the seed layer acting as a nucleation site for the plating process. The plating process may be an electroless plating process or an electroplating process. Cu, a Cu alloy, Ni, a Ni alloy, Au or aluminum (Al), for example, may be plated onto the seed layer. In some implementations, the plated metal may not be the same metal as a metal of the seed layer. In some other implementations, the plated metal may be the same metal as a metal of the seed layer.

In some implementations, a photoresist may be used to define the portions of the seed layer onto which a metal will be plated. After plating the metal, the seed layer remaining on the surfaces of the glass substrate onto which the metal was not plated may be removed. For example, the seed layer may be removed with an etching process.

FIG. 2C shows examples of schematic illustrations of the fabricated inductor 1000 at this point (e.g., up through block 108) in the process 100A. The inductor 1000 includes the glass substrate 1002 having the area 1010 exposed to ultraviolet light. Metal layer 1020 is disposed on the glass substrate 1002, at least partially filling the vias and forming a trace 1022 connecting the metal of different vias. In some implementations, the metal layer 1020 may include Cu, a Cu alloy, Ni, a Ni alloy, Au, an Au alloy, or Al. In some implementations, the metal layer 1020 may be about 0.5 microns to 30 microns thick. As shown in FIG. 2C, the metal layer 1020 may substantially fill the vias. In other some implementations, however, the metal layer 1020 may not substantially fill the vias.

In some implementations, the fabrication of the inductor 1000 as shown in FIG. 2C is complete after performing blocks 102, 106, and 108 of FIG. 1A. Thus, portions of the glass substrate 1002 remain embedded in the inductor 1000 in such implementations. In some other implementations, as described below with reference to FIG. 1B, the inductor 1000 as shown in FIG. 2C is partially fabricated before performing additional processing blocks.

The process 100B of FIG. 1B includes blocks 102, 106, and 108 of FIG. 1A as described above. In addition, the example of FIG. 1B includes a block 110, at which a dielectric layer is deposited on a first side and on a second side of the glass substrate. In some implementations, the dielectric layers may be deposited with a lamination process. In some implementations, the dielectric layers may include a polyimide, benzocyclobutene (BCB), or a Zeon insulated film such as polyolefin.

In some implementations, after the dielectric layers are deposited, portions of the dielectric layers may be removed from the first side and/or the second side of the glass substrate to expose some of the area of the glass substrate exposed to ultraviolet light and some of the metal layer. In some implementations, the portions of the dielectric layers may be removed with a laser etching process or a photolithography process combined with a chemical etching process or a plasma chemical etching process.

FIG. 2D shows examples of schematic illustrations of the partially fabricated inductor 1000 at this point (e.g., up through block 110) in the process 100B. The inductor 1000 includes the glass substrate 1002 having the area 1010 exposed to ultraviolet light. The metal layer 1020 is disposed on the glass substrate 1002, at least partially filling the vias and forming traces connecting the metal of different vias. A first dielectric layer 1024 is disposed on a first side of the glass substrate 1002 and a second dielectric layer 1026 is disposed on a second side of the glass substrate 1002. In some implementations, the dielectric layers 1024 and 1026 may include a polyimide, benzocyclobutene, or a Zeon insulated film. Portions of the dielectric layers 1024 and 1026 have been removed to expose a region of the metal layer 1020 and of the area 1010 of the glass substrate 1002 exposed to ultraviolet light. In some implementations, the dielectric layers 1024 and 1026 may be about 10 microns to 250 microns thick.

Returning to FIG. 1B, at block 112 the area of the glass substrate exposed to ultraviolet light is removed. In some implementations, the glass substrate exposed to ultraviolet light may be removed with a chemical etching process. Exposing the area of a photoimageable glass to ultraviolet light and then exposing the photoimageable glass to an elevated temperature may result in a change of the structural and/or chemical properties of the area exposed to ultraviolet light. As a result, this exposed area may have a higher etch rate than the unexposed area of the photoimageable glass.

FIG. 2E shows examples of schematic illustrations of the inductor 1000 at this point (e.g., up through block 112) in the process 100B. The inductor 1000 includes the glass substrate 1002 with the first dielectric layer 1024 disposed on the first side of the glass substrate 1002 and the second dielectric layer 1026 disposed on the second side of the glass substrate 1002. Together, an open region of the glass substrate 1002, the first dielectric layer 1024, and the second dielectric layer 1026 form a cavity 1030. The metal layer 1020 is disposed on the glass substrate 1002 and also forms bars of metal in the cavity 1030.

In some implementations, the processes 100A or 100B may include additional process operations. For example, in some implementations, the adhesion of the metal layer to the glass substrate may be insufficient. For example, when the metal layer is plated onto the glass substrate, the seed layer may delaminate from the glass substrate. As another example, the metal layer may not plate at all onto the surfaces of the glass substrate.

To improve the adhesion of the metal layer to the glass substrate, the processes 100A or 100B may include the additional process operation of depositing a dielectric adhesion layer on the surfaces of the glass substrate, including the surfaces defining the vias, before depositing the metal layer. In some implementations, the dielectric adhesion layer may include an oxide layer. For example, the dielectric adhesion layer may include SiO₂, Al₂O₃ (aluminum oxide), ZrO₂ (zirconium oxide), hafnium oxide (HfO₂), yttrium oxide (Y₂O₃), tantalum oxide (TaO₂), a SrO/TiO₂ (strontium oxide/titanium oxide) mixture, or SiO₂ doped with other oxides.

In some implementations, the dielectric adhesion layer may be deposited with an ALD process. ALD is a thin-film deposition technique performed with one or more chemical reactants, also referred to as precursors. For example, in some implementations, an Al₂O₃ dielectric adhesion layer may be deposited using trimethyl aluminum (TMA) as an aluminum precursor gas and at least one of water (H₂O) or ozone (O₃) as an oxygen precursor gas. Other suitable precursor gases are also available. For example, other suitable aluminum precursor gases include tri-isobutyl aluminum (TIBAL), tri-ethyl/methyl aluminum (TEA/TMA), and dimethylaluminum hydride (DMAH). In some implementations, the dielectric adhesion layer may be about 5 nm to 20 nm thick, or about 5 nm thick. In some implementations, depositing a dielectric adhesion layer of about 5 nm thick may be achieved with about 100 ALD process cycles.

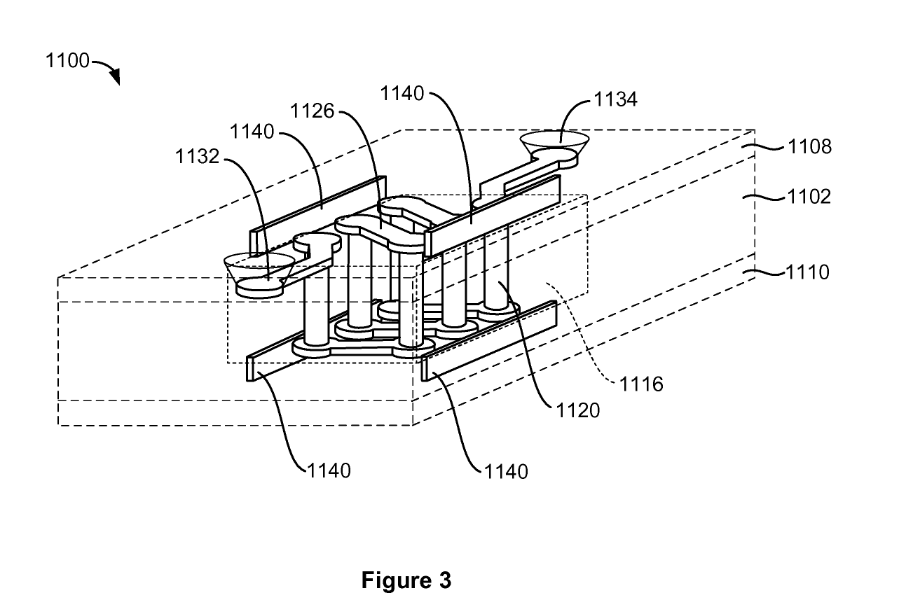

FIG. 3 is an example of an isometric projection of a through glass via inductor including an air core. An inductor 1100 includes a glass substrate 1102 having a first dielectric layer 1108 disposed on a first surface of the glass substrate 1102 and a second dielectric layer 1110 disposed on a second surface of the glass substrate 1102. In some implementations, the glass substrate 1102 includes a photoimageable glass. In some implementations, the glass substrate 1102 may be about 30 microns to 1 mm thick, or about 500 microns thick. In some implementations, the dielectric layers 1108 and 1110 may be about 10 microns to 250 microns thick. Together, an open region defined in the glass substrate 1102, the first dielectric layer 1108, and the second dielectric layer 1110 define a cavity 1116. The cavity 1116 may have a width of about 100 microns to a few millimeters.

The cavity 1116 includes at least two metal bars, one of which is a metal bar 1120. The inductor 1100 includes six metal bars 1120. A first end of each metal bar 1120 is proximate the first dielectric layer 1108 and a second end of each metal bar is proximate the second dielectric layer 1110. In some implementations, the at least two metal bars are hollow metal bars, and in some other implementations, the at least two metal bars are solid metal bars. In some implementations, the metal bars may include Cu, a Cu alloy, Ni, a Ni alloy, Au or Al. In some implementations, the metal bars may have a cross-sectional dimension of about 30 microns to 400 microns. For example, when the metal bars are cylinders, the metal bars may have a diameter of about 30 microns to 400 microns. Metal traces, one of which is a trace 1126, connect a first metal bar with a second metal bar. In some implementations, the metal traces may include Cu, a Cu alloy, Ni, a Ni alloy, Au or Al. In some implementations, the metal traces may be about 0.5 microns to 20 microns thick. Points 1132 and 1134 provide points where metal traces of the inductor 1100 may be connected to a current source. Channels 1140 in the first dielectric layer 1108 and the second dielectric layer 1110 provide a region where the glass substrate 1102 can be etched to form the cavity 1116.

The manufacturing processes 100A and 100B shown in FIGS. 1A and 1B may be used to fabricate a through glass via inductor having a number of different configurations. For example, an inductor having any number of turns, such as a half turn, 1 turn, 10 turns, 10.5 turns, 25 turns and 50 turns, may be fabricated with the manufacturing processes 100A and 100B.

In some implementations, the manufacturing processes 100A and 100B may include additional process operations to form a magnetic core for the through glass via inductor. Thus, an inductor may include a magnetic core disposed in the air core. In some implementations, a magnetic core may increase the inductance of a through glass via inductor.

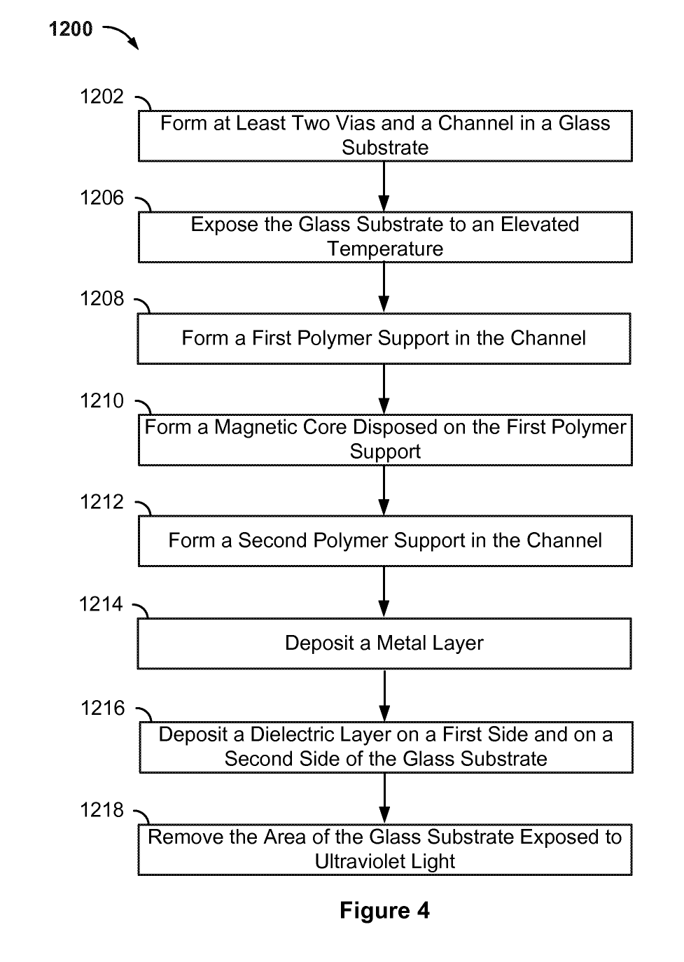

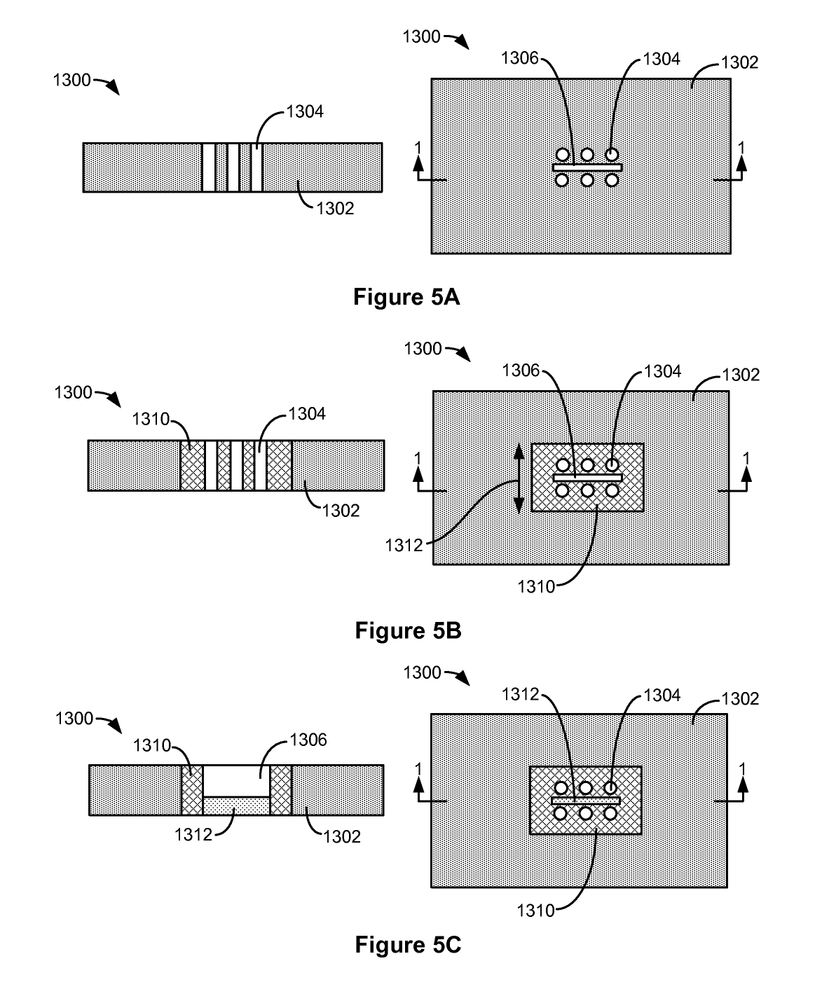

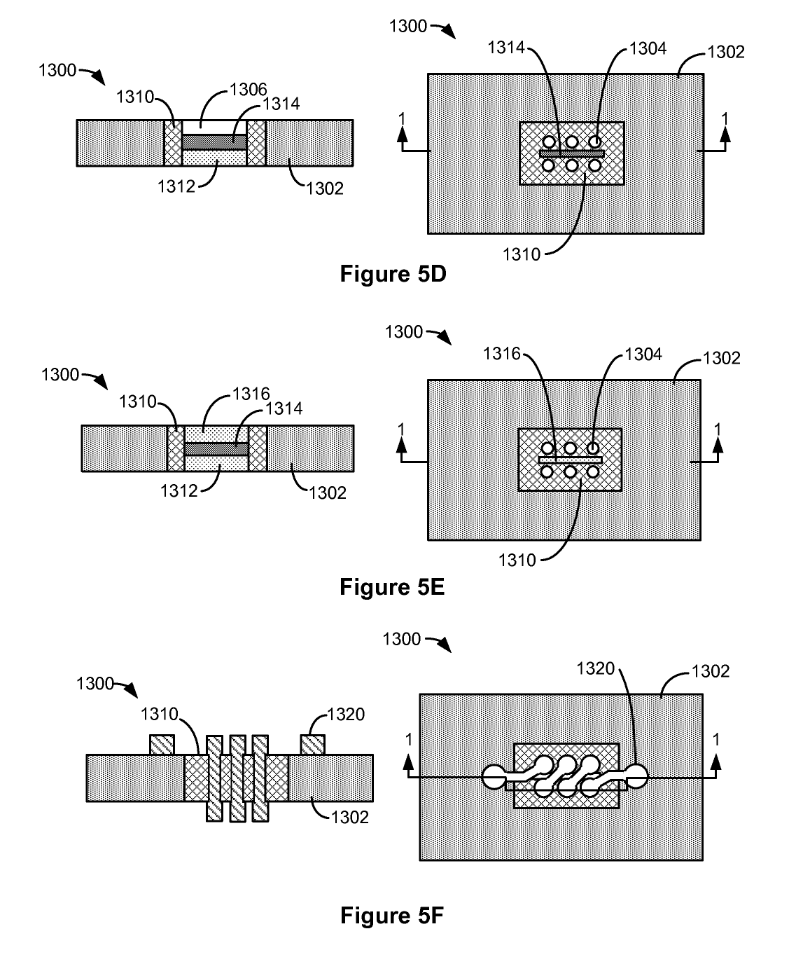

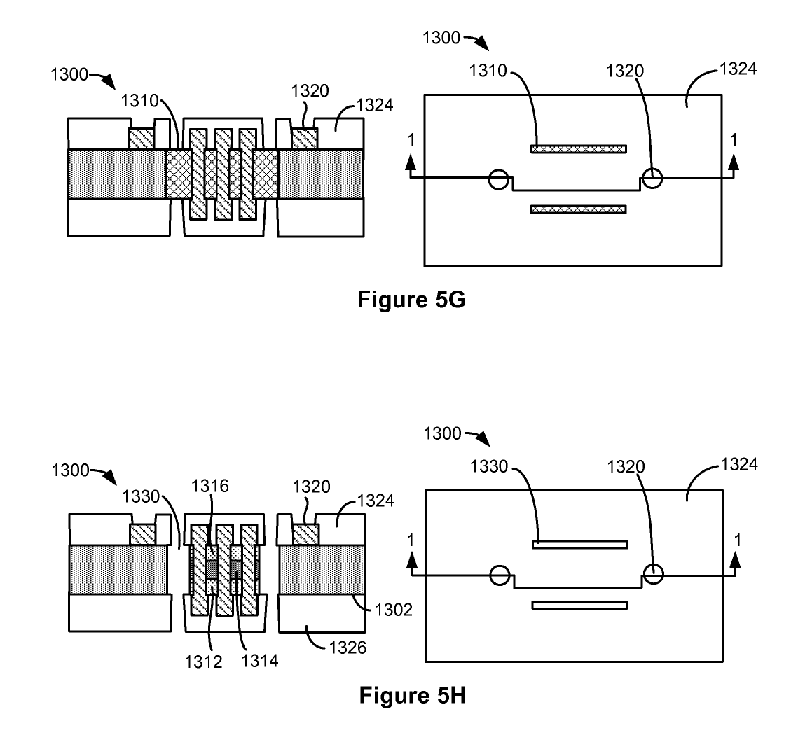

For example, another implementation of a manufacturing process for a through glass via inductor, accompanied by top-down and cross-sectional schematic illustrations of an inductor at various stages in the manufacturing process, is set forth below with respect to FIGS. 4 and 5A-5H. FIG. 4 is an example of a flow diagram illustrating a manufacturing process for a through glass via inductor including a magnetic core. FIGS. 5A-5H are examples of schematic illustrations of a through glass via inductor including a magnetic core at various stages in the manufacturing process. Each of FIGS. 5A-5H includes an example of a cross-sectional schematic illustration of the inductor through line 1-1 in the corresponding top-down schematic illustration. In some implementations, a process 1200 shown in FIG. 4 may include similar process operations as one or both of the processes 100A and 100B shown in FIGS. 1A and 1B.

In the process 1200 shown in FIG. 4, patterning techniques, including masking as well as etching processes, may be used to define the shapes of the different components of an inductor. At block 1202 of the process 1200, at least two vias and a channel are formed in a glass substrate. As mentioned above with respect to FIG. 1A, in some implementations, upper and/or lower surfaces of the glass substrate may be coated with a TGP before forming the vias and the channel at block 1202, as described in greater detail below with respect to FIG. 16G. In some implementations, the glass substrate may be a photoimageable glass. Different process, including laser ablation processes, media blasting processes, etching processes, or photoimageable glass processing, techniques may be used to form the at least two vias and the channel in the glass substrate.

FIG. 5A shows examples of schematic illustrations of the partially fabricated inductor at this point (e.g., up through block 1202) in the process 1200. An inductor 1300 includes a glass substrate 1302 defining at least two vias, one via which is a via 1304. The glass substrate 1302 further defines a channel 1306, the channel 1306 passing between the at least two vias. In some implementations, the photoimageable glass substrate 1302 may have the same or similar thicknesses as substrate 1002 and via 1004 described above with reference to FIG. 2A. In some implementations, the channel 1306 may have a length that spans the vias in the glass substrate. The channel 1306 and the at least two vias also may include at least a portion of the glass substrate 1302 between them.

Returning to FIG. 4, an area of the glass substrate where a cavity is to be formed can be exposed to ultraviolet light. In some implementations, the area where the cavity is to be formed includes the at least two vias and the channel formed in operation 1202. At block 1206, the glass substrate is exposed to an elevated temperature. Exposing an area of a photoimageable glass to ultraviolet light and then exposing the photoimageable glass to an elevated temperature may result in a change of the structural and/or chemical properties of the area exposed to ultraviolet light. As a result, this exposed area may have a higher etch rate than the unexposed area of the photoimageable glass.

FIG. 5B shows examples of schematic illustrations of the partially fabricated inductor 1300 at this point (e.g., up through block 1206) in the process 1200. The inductor 1300 includes the glass substrate 1302 defining at least two vias, one via which is the via 1304, and the channel 1306. Area 1310 is the area of the glass substrate 1302 exposed to ultraviolet light. The area 1310 may have a width 1311 of about 100 microns to a few millimeters.

Returning to FIG. 4, at block 1208 a first polymer support is formed in a portion of the channel. In some implementations, the first polymer support may be formed by depositing a polymer material on the second side of the glass substrate. Polymer material not proximate the channel may be removed with an etching process. Polymer material not proximate the channel may include polymer material overlying the at least two vias and polymer material deposited on other regions of the second side of the glass substrate. The polymer material may then be reflowed into the channel, partially filling the channel. To reflow the polymer material, the polymer material may be heated and then pulled into the channel by applying a vacuum to the other end of the channel. Examples of suitable polymer materials include a polyimide, BCB, epoxy, various poly (p-xylylene) polymers, epoxy-based negative photoresists such as SU-8, and/or a Zeon insulating film such as polyolefin.

In some other implementations, the first polymer support may be formed by depositing a polymer material on the second side of the glass substrate. The polymer material may then be reflowed into the channel, partially filling the channel. To reflow the polymer material, the polymer material may be heated and then pulled into the channel by applying a vacuum to the other end of the channel. The polymer material overlying the at least two vias also may be reflowed into the vias. The polymer material that was reflowed into the at least two vias and the polymer material remaining on the second side of the glass substrate may be removed with an etching process, such as a laser etching process, for example.

FIG. 5C shows examples of schematic illustrations of the partially fabricated inductor 1300 at this point (e.g., up through block 1208) in the process 1200. The inductor 1300 includes the glass substrate 1302 defining at least two vias, one via which is the via 1304, and the channel 1306. The channel 1306 includes a first polymer support 1312 disposed in it. The area 1310 is the area of the glass substrate 1302 exposed to ultraviolet light.

Returning to FIG. 4, at block 1210 a magnetic core is formed on the first polymer support in the channel. In some implementations, forming the magnetic core may include depositing a material including a bulk ferromagnetic or ferrimagnetic material, or a polymer and particles of a ferromagnetic material or a ferrimagnetic material in the channel. Depositing the material including the polymer and the particles may include a spin-on process, for example. Examples of ferromagnetic materials and ferrimagnetic materials include iron (Fe), Ni, cobalt (Co), alloys of Fe, Ni and Co, and ferrites. In some implementations, the particle size of the particles may be few nanometers to tens of microns or larger. In some implementations, the polymer may include an epoxy. In some implementations, the polymer may be cured with, for example, heat or ultraviolet light. In some implementations, the ferrite is a discrete ferrite core that has been sintered previously.

In some other implementations, forming a magnetic core may include electroplating a ferromagnetic material or a ferrimagnetic material in the channel. In some implementations, a seed layer may first be deposited onto a surface of the first polymer support and surfaces of the channel. In some implementations, the seed layer may be deposited using a CVD process, an evaporation process, an ALD process, or an electroless plating process. Then, the ferromagnetic of ferrimagnetic material may be plated onto the seed layer using an electroplating process or an electroless plating process.

FIG. 5D shows examples of schematic illustrations of the partially fabricated inductor 1300 at this point (e.g., up through block 1210) in the process 1200. The inductor 1300 includes the glass substrate 1302 defining at least two vias, one via which is the via 1304, and the channel 1306. The channel 1306 includes a first polymer support 1312 disposed in it and a magnetic core 1314 disposed on the first polymer support 1312. The area 1310 is the area of the glass substrate 1302 exposed to ultraviolet light.

Returning to FIG. 4, at block 1212 a second polymer support is formed on the magnetic core in the channel. The second polymer support may be formed in a manner similar to the manner in which the first polymer support was formed at block 1208. For example, in some implementations, the second polymer support may be formed by depositing a polymer material on the first side of the glass substrate. Polymer material not proximate the channel may be removed with an etching process. Polymer material not proximate the channel may include polymer material overlying the at least two vias and polymer material deposited on other regions of the first side of the glass substrate. The polymer material may then be reflowed into the channel, filling the channel. To reflow the polymer material, the polymer material may be heated and then pushed into the channel by applying a pressure to the polymer material or pulled into the channel by introducing a vacuum.

In some other implementations, the second polymer support may be formed by depositing a polymer material on the first side of the glass substrate. The polymer material may then be reflowed into the channel by heating the polymer material and applying a pressure to it to force it into the channel. The polymer material overlying the at least two vias also may be reflowed into the vias. The polymer material that was reflowed into the at least two vias and the polymer material remaining on the first side of the glass substrate may be removed with an etching process, such as a laser etching process, for example.

FIG. 5E shows examples of schematic illustrations of the partially fabricated inductor 1300 at this point (e.g., up through block 1212) in the process 1200. The inductor 1300 includes the glass substrate 1302 defining at least two vias, one via which is the via 1304. The channel includes the first polymer support 1312 disposed in it, the magnetic core 1314 disposed on the first polymer support 1312, and a second polymer support 1316 disposed on the magnetic core 1314. The area 1310 is the area of the glass substrate 1302 exposed to ultraviolet light.

Returning to FIG. 4, at block 1214 a metal layer is deposited. In some implementations, the deposited metal layer at least partially fills the vias and forms traces connecting the vias. For example, when two vias are present, a trace may connect the metal of a first via with the metal of a second via.

In some implementations, a dry film mask may be used to define the regions of the glass substrate onto which the metal layer is deposited. In some implementations, the dry film mask may be of a photo-sensitive polymer. In some implementations, the metal layer may be deposited using a PVD process or a CVD process. In some other implementations, the metal layer may be deposited using a plating process, including depositing a seed layer onto surfaces of the glass substrate and depositing the metal layer using a plating process, for example. The plating process may be an electroless plating process or an electroplating process.

FIG. 5F shows examples of schematic illustrations of the partially fabricated inductor 1300 at this point (e.g., up through block 1214) in the process 1200. The inductor 1300 includes the glass substrate 1302 having the area 1310 exposed to ultraviolet light. Metal layer 1320 is disposed on the glass substrate 1302, at least partially filling the vias and forming a trace 1322 connecting the metal of different vias. In some implementations, the metal layer 1320 may include Cu, a Cu alloy, Ni, a Ni alloy, Au or Al. In some implementations, the metal layer 1320 may be about 0.5 microns to 30 microns thick. As shown in FIG. 5F, the metal layer 1320 may substantially fill the vias. In other some implementations, however, the metal layer 1320 may not substantially fill the vias.

Returning to FIG. 4, at block 1216 a dielectric layer is deposited on the first side and on the second side of the glass substrate. In some implementations, the dielectric layers may be deposited with a lamination process. In some implementations, the dielectric layer may include a polyimide, benzocyclobutene, or a Zeon insulated film.

In some implementations, after the dielectric layers are deposited, portions of the dielectric layers may be removed from the first side and/or the second side of the glass substrate to expose some of the area of the glass substrate exposed to ultraviolet light and some of the metal layer. In some implementations, the portions of the dielectric layers may be removed with a laser etching process or a photolithography process combined with a chemical etching process or a plasma chemical etching process.

FIG. 5G shows examples of schematic illustrations of the partially fabricated inductor 1300 at this point (e.g., up through block 1216) in the process 1200. The inductor 1300 includes the glass substrate 1302 having the area 1310 exposed to ultraviolet light. The metal layer 1320 is disposed on the glass substrate 1302, at least partially filling the vias and forming traces connecting the metal of different vias. A first dielectric layer 1324 is disposed on a first side of the glass substrate 1302 and a second dielectric layer 1326 disposed on a second side of the glass substrate 1302. In some implementations, the dielectric layers 1324 and 1326 may include a polyimide, benzocyclobutene, or a Zeon insulated film. Portions of the dielectric layers 1324 and 1326 have been removed to expose the metal layer 1320 and the area 1310 of the glass substrate 1302 exposed to ultraviolet light. In some implementations, the dielectric layers 1324 and 1326 may be about 10 microns to 250 microns thick.

Returning to FIG. 4, at block 1218 the area of the glass substrate exposed to ultraviolet light is removed. In some implementations, the glass substrate exposed to ultraviolet light may be removed with a chemical etching process. Exposing the area of a photoimageable glass to ultraviolet light and then exposing the photoimageable glass to an elevated temperature may result in a change of the structural and/or chemical properties of the area exposed to ultraviolet light. As a result, this exposed area may have a higher etch rate than the unexposed area of the photoimageable glass.

FIG. 5H shows examples of schematic illustrations of the inductor 1300 at this point (e.g., up through block 1218) in the process 1200. The inductor 1300 includes the glass substrate 1302, the first dielectric layer 1324 disposed on a first side of the glass substrate 1302, and the second dielectric layer 1326 disposed on a second side of the glass substrate 1302. Together, an open region in the glass substrate 1302, the first dielectric layer 1324, and the second dielectric layer 1326 define a cavity 1330. The metal layer 1320 is disposed on the glass substrate 1302 and also forms bars of metal in the cavity 1330. The inductor 1300 further includes the first polymer support 1312, the magnetic core 1314 disposed on the first polymer support 1312, and the second polymer support 1316 disposed on the magnetic core 1314.

The manufacturing process 1200 shown in FIG. 4 may be used to fabricate a through glass via inductor, as described above. In some implementations, the process 1200 may include additional process operations. In some implementations, the process 1200 may include the additional process operation of depositing a dielectric adhesion layer on the glass substrate, including the surfaces defining the vias, before depositing the metal layer. A dielectric adhesion layer may improve the adhesion of the metal layer to the glass substrate. In some implementations, a dielectric adhesion layer may be deposited with an ALD process.

In some other implementations, a variation of the process 1200 is performed in which blocks 1216 and 1218 are omitted, similar to the difference between the processes 100A and 100B. Thus, in such implementations, the fabrication of the inductor 1300 as shown in FIG. 5F is complete after performing blocks 1202-1214 of FIG. 4. Thus, the glass substrate 1302 remains in the inductor 1300 in such implementations.

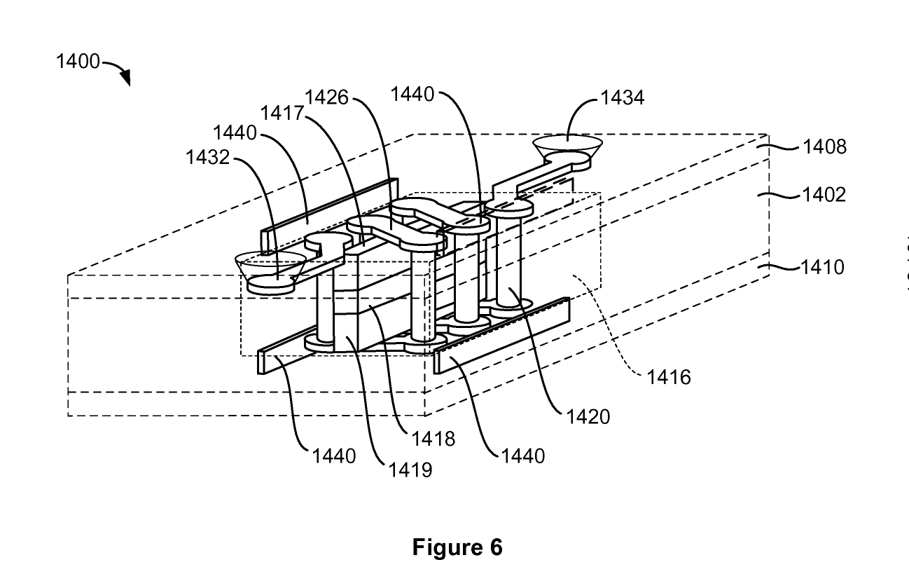

FIG. 6 is an example of an isometric projection of a through glass via inductor including a magnetic core. An inductor 1400 may be similar to the inductor 1100 shown in FIG. 3, with the addition of a magnetic core. The inductor 1400 includes a glass substrate 1402 having a first dielectric layer 1408 disposed on a first surface of the glass substrate 1402 and a second dielectric layer 1410 disposed on a second surface of the glass substrate 1402. In some implementations, the glass substrate 1402 includes a photoimageable glass. In some implementations, the glass substrate 1402 may be about 30 microns to 1 mm thick, or about 500 microns thick. In some implementations, the dielectric layers 1408 and 1410 may be about 10 microns to 250 microns thick. Together, an open region defined in the glass substrate 1402, the first dielectric layer 1408, and the second dielectric layer 1410 define a cavity 1416. The cavity 1416 may have a width of about 100 microns to a few millimeters.

Disposed within the cavity 1416 are polymer supports, 1417 and 1419, each in contact with the first dielectric layer 1408 and the second dielectric layer 1410, respectively. In between the polymer supports 1417 and 1419 is a magnetic core 1418. In some implementations, the magnetic core 1418 may include a ferromagnetic material or a ferrimagnetic material, such as Fe, Ni, Co, alloys of Fe, Ni and Co, or ferrites.

The cavity 1416 also includes at least two metal bars, one of which is a metal bar 1420. The inductor 1400 includes six metal bars 1420. A first end of each metal bar 1420 is proximate the first dielectric layer 1408 and a second end of each metal bar is proximate the second dielectric layer 1410. In some implementations, the at least two metal bars are hollow metal bars, and in some other implementations, the at least two metal bars are solid metal bars. In some implementations, the metal bars may include Cu, a Cu alloy, Ni, a Ni alloy, Au or Al. In some implementations, the metal bars have a cross-sectional dimension of about 30 microns to 400 microns. For example, when the metal bars are cylinders, the metal bars may have a diameter of about 30 microns to 500 microns. Metal traces, one of which is trace 1426, connect a first metal bar with a second metal bar. In some implementations, the metal traces may include Cu, a Cu alloy, Ni, a Ni alloy, Au or Al. In some implementations, the metal traces may be about 0.5 microns to 20 microns thick. Points 1432 and 1434 provide points where metal traces of the inductor 1400 may be connected to a current source. Channels 1440 in the first dielectric layer 1408 and the second dielectric layer 1410 provide a region where the glass substrate 1402 can be etched to form the cavity 1416.

In some implementations, any of the examples of through glass via inductors described herein can be incorporated in circuitry and devices of various feedback applications in which variable inductance values are desirably sensed. For example, when the glass substrate is thin enough to permit some flexibility, for instance, about 200 microns thick or less, a degree of flexing imposed on or otherwise occurring in the glass will cause a corresponding change in the inductance value of any of the examples of soleinoidal or toroidal inductors as disclosed herein. In some other implementations, the glass substrate of the inductor formed using the techniques described above can be etched away after coating the inductor with a suitable polymer film, on the top and/or bottom sides. The resulting polymer-coated inductor absent the glass substrate can be flexible. Various feedback circuit configurations can incorporate such a flexible inductor or can be coupled to the flexible inductor, for example, using integrated or discrete circuit components. The inductor can serve as a sensor, and feedback circuitry can be configured to monitor the varying inductance of the inductor to determine the corresponding degree of flexing. For instance, the inductor can be implemented as a strain or displacement sensor, for instance, by being configured to provide an output signal at an output terminal of the inductor in response to an input. The input can be a mechanical strain or displacement imposed by an external force on the flexible inductor or flexible substrate in which the inductor is situated. In some instances, the input also includes an electronic signal provided to an input terminal of the inductor. The output signal can be provided to feedback or sensing circuitry coupled to interpret from the output signal a corresponding degree of the mechanical strain or displacement. In some implementations, various resonator circuit configurations, such as an LC tank, can incorporate a flexing inductor constructed in the manners described above coupled in series, in parallel, or in another circuit with a capacitor. When a signal is applied to the LC tank, changes in the resonant frequency of the resonator circuit can indicate a degree of flexing of the inductor, and such changes can be sensed by frequency detection circuitry coupled to the LC tank.

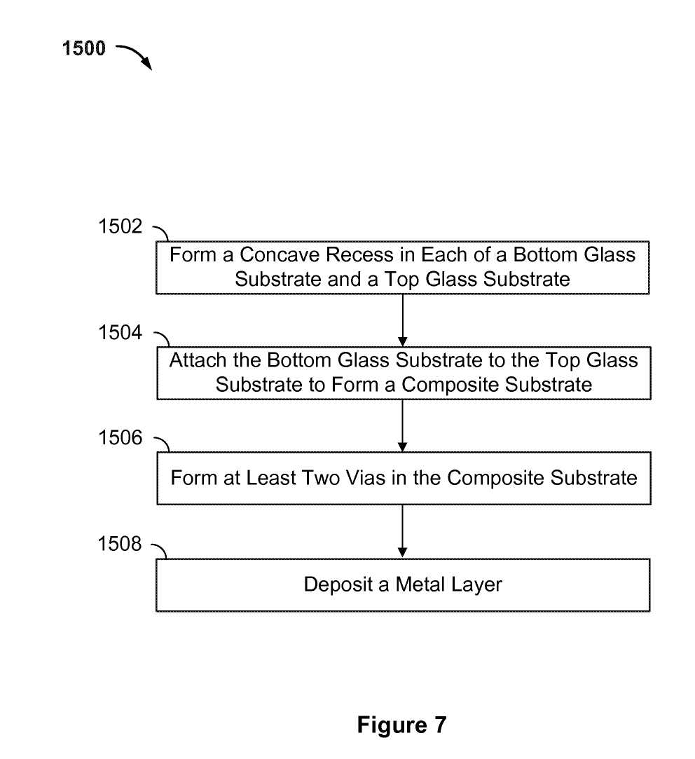

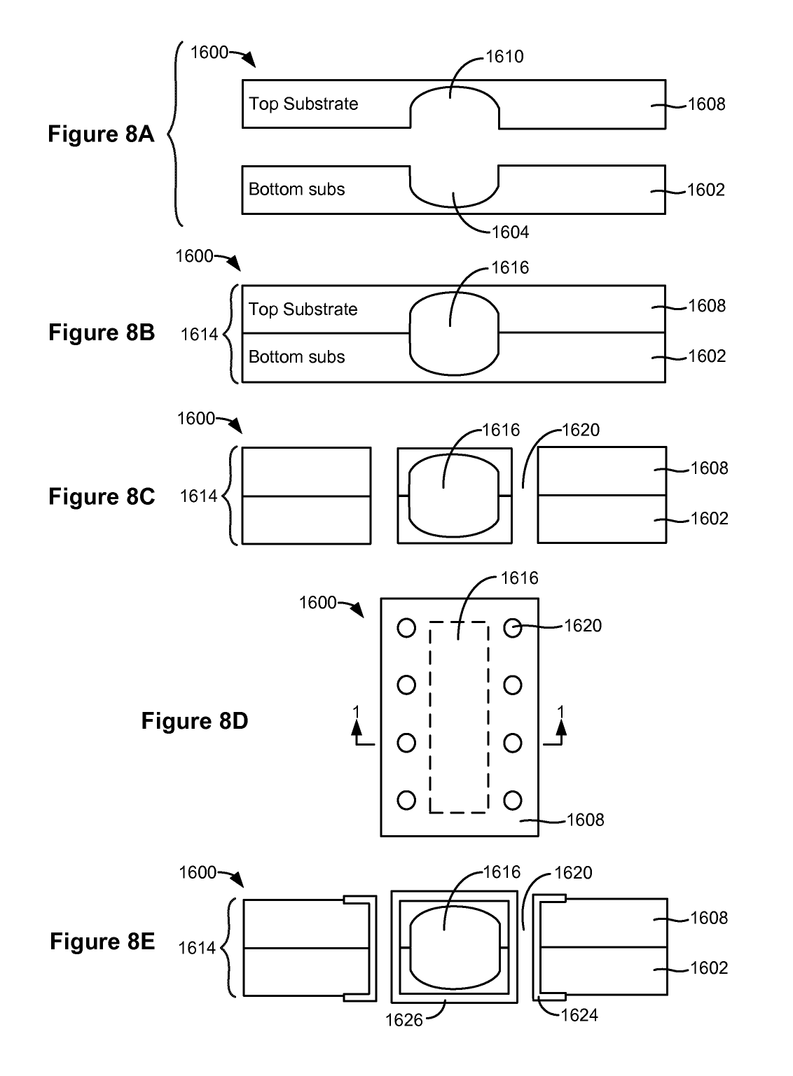

Another implementation of a manufacturing process for a through glass via inductor including two substrates, accompanied by top-down and cross-sectional schematic illustrations of an inductor at various stages in the manufacturing process, is set forth below with respect to FIGS. 7 and 8A-8E. FIG. 7 is an example of a flow diagram illustrating a manufacturing process for a through glass via inductor including two substrates. FIGS. 8A-8E are examples of schematic illustrations of a through glass via inductor including two substrates at various stages in the manufacturing process.

In a process 1500 shown in FIG. 7, patterning techniques, including masking as well as etching processes, may be used to define the shapes of the different components of an inductor. At block 1502 of the process 1500, a concave recess is formed in each of a bottom glass substrate and a top glass substrate. In some implementations, the glass substrates may include a display glass, a borosilicate glass, or a photoimageable glass.

Different processes, depending on the glass of the glass substrate, may be used to form the concave recesses in the glass substrates. For example, for some glasses, such as a display glass or a borosilicate glass, a laser ablation process, a sandblasting process, or an etching process (e.g., a chemical wet etching process or a dry reactive ion-etching process) may be used to form the concave recess. In some other implementations, for a photoimageable glass, the concave recess may be formed by exposing the glass substrate where the concave recess is to be formed to ultraviolet light, exposing the glass substrate to an elevated temperature, and etching the concave recess with an acid.

FIG. 8A shows an example of a cross-sectional schematic illustration of the partially fabricated inductor at this point (e.g., up through block 1502) in the process 1500. An inductor 1600 includes a bottom glass substrate 1602 including a concave recess 1604 and a top glass substrate 1608 including a concave recess 1610. In some implementations, the bottom glass substrate 1602 and the top glass substrate 1608 may be about 100 microns to 1 mm thick, or about 500 microns thick.

Returning to FIG. 7, at block 1504 the bottom glass substrate is attached to the top glass substrate. Different techniques may be used to attach the bottom glass substrate to the top glass substrate. In some implementations, the bottom glass substrate and the top glass substrate may be attached to one another with an adhesive. For example, the adhesive may be an epoxy, including an air curable epoxy, an ultraviolet light curable epoxy or a thermally curable epoxy. In some implementations, the bottom glass substrate and the top glass substrate may be attached to one another with a glass frit bond ring. In some implementations, the bottom glass substrate and the top glass substrate may be attached to one another with a fusion bond or an anodic bond.

In some implementations, the bottom glass substrate and the top glass substrate may be attached to one another with a metal bond ring. The metal bond ring may include a solderable metallurgy, a eutectic metallurgy, a solder paste, or the like. Examples of solderable metallurgies include nickel/gold (Ni/Au), nickel/palladium (Ni/Pd), nickel/palladium/gold (Ni/Pd/Au), Cu, and gold (Au). Eutectic metal bonding involves forming a eutectic alloy layer between the bottom glass substrate and the top glass substrate. Examples of eutectic alloys that may be used include indium bismuth (InBi), copper tin (CuSn), and gold tin (AuSn). Melting temperatures of these eutectic alloys are about 150° C. for the InBi eutectic alloy, about 225° C. for the CuSn eutectic alloy, and about 305° C. for the AuSn eutectic alloy. Direct room temperature metal to metal fusion bonding is also a method of joining the bottom and top glass substrates. An example of direct room temperature metal fusion bonding is made by Mitsubishi Heavy Industries, Ltd. of Yokohama, Japan.

FIG. 8B shows an example of a cross-sectional schematic illustration of the partially fabricated inductor 1600 at this point (e.g., up through block 1504) in the process 1500. The inductor 1600 includes the bottom glass substrate 1602 attached to the top glass substrate 1608 forming a composite substrate 1614. The concave recesses in the bottom glass substrate 1602 and the top glass substrate 1608 define a cavity 1616 in the composite substrate 1614. In some implementations, the cavity 1616 may have a rectangular-shaped cross-section or a circular-shaped cross-section applicable to a solenoid configuration or a toroid configuration of the inductor. In some implementations, the cavity 1616 may have a cross-sectional dimension of about 50 microns to a few millimeters. For example, when the cavity 1616 is shaped like a cylinder, the diameter of the cavity may be about 50 microns to a few millimeters.

Returning to FIG. 7, at block 1506 at least two vias are formed in the composite substrate. Also, as with some of the examples mentioned above, in some implementations, upper and/or lower surfaces of the composite substrate may be coated with a TGP before forming the vias at block 1506, as described in greater detail below with respect to FIG. 16G. Different processes, depending on the glass of the composite substrate, may be used to form the at least two vias in the composite substrate. For example, when the composite substrate includes a display glass or a borosilicate glass, a laser ablation process, a sandblasting process, or an etching process, or a combination thereof, may be used to form the at least two vias. When the composite substrate includes a photoimageable glass, the at least two vias may be formed by exposing the composite substrate where the at least two vias are to be formed to ultraviolet light, exposing the composite substrate to an elevated temperature, and etching the at least two vias with an acid.

FIGS. 8C and 8D show examples of schematic illustrations of the partially fabricated inductor 1600 at this point (such as up through block 1506) in the process 1500. FIG. 8C shows an example of a cross-sectional schematic illustration of the inductor through line 1-1 in the top-down schematic illustration shown in FIG. 8D. Further, FIG. 8D shows the top glass substrate 1608 and an outline indicating the position of the cavity 1616. As shown in FIG. 8D, in some implementations, the cavity 1616 may be enclosed on all sides. The inductor 1600 includes the bottom glass substrate 1602 attached to the top glass substrate 1608 forming the composite substrate 1614. The concave recesses in the bottom glass substrate 1602 and the top glass substrate 1608 define the cavity 1616 in the composite substrate 1614. The composite substrate 1614 further defines at least two vias, one via which is a via 1620. In some implementations, the vias may have a cross-sectional dimension of about 30 microns to 500 microns. For example, when the vias are cylindrical, the vias may have a diameter of about 30 microns to 500 microns.

Returning to FIG. 7, at block 1508, a metal layer is deposited. The deposited metal layer at least partially fills the vias and forms traces connecting the vias. For example, when two vias are present, a trace may connect the metal of a first via with the metal of a second via. The vias and the traces may bound the cavity, surround the cavity, or define borders with respect to the cavity.

In some implementations, a dry film mask may be used to define the regions of the composite substrate onto which the metal layer is deposited. In some implementations, the dry film mask may be of a photo-sensitive polymer. In some implementations, the metal layer may be deposited using a PVD process or a CVD process.

In some other implementations, the metal layer may be deposited using a plating process. For example, a seed layer may first be deposited over surfaces of the composite substrate. In some implementations, the seed layer may be deposited using a CVD process, an ALD process, or an electroless plating process. In some implementations, the seed layer may be about 25 nm to 500 nm thick. After the seed layer is deposited, the metal layer may be deposited using a plating process, with the seed layer acting as a nucleation site for the plating process. The plating process may be an electroless plating process or an electroplating process. Cu, a Cu alloy, Ni, a Ni alloy, Au or Al, for example, may be plated onto the seed layer. In some implementations, the plated metal may not be the same metal as a metal of the seed layer. In some other implementations, the plated metal may be the same metal as a metal of the seed layer.

In some implementations, a photoresist may be used to define the portions of the seed layer onto which a metal will be plated. After plating the metal, the seed layer remaining on the surfaces of the composite substrate onto which the metal was not plated may be removed. For example, the seed layer may be removed with an etching process.

FIG. 8E shows an example of a cross-sectional schematic illustration of the inductor 1600 at this point (such as up through block 1508) in the process 1500. The inductor 1600 includes the bottom glass substrate 1602 attached to the top glass substrate 1608 forming a composite substrate 1614. The concave recesses in the bottom glass substrate 1602 and the top glass substrate 1608 define a cavity 1616 in the composite substrate 1614. The composite substrate 1614 further defines at least two vias, one via which is a via 1620. Metal layer 1624 is disposed on the composite substrate 1614, at least partially filling the vias and forming a trace 1626 connecting the metal of different vias. In some implementations, the metal layer 1624 may include Cu, a Cu alloy, Ni, a Ni alloy, Au or Al. In some implementations, the metal layer 1624 may be about 0.5 microns to 30 microns thick. In some implementations, the vias and the traces may be proximate the borders with respect to the cavity 1616. As shown in FIG. 8E, the metal layer 1624 may not substantially fill the vias. In other some implementations, however, the metal layer may substantially fill the vias.

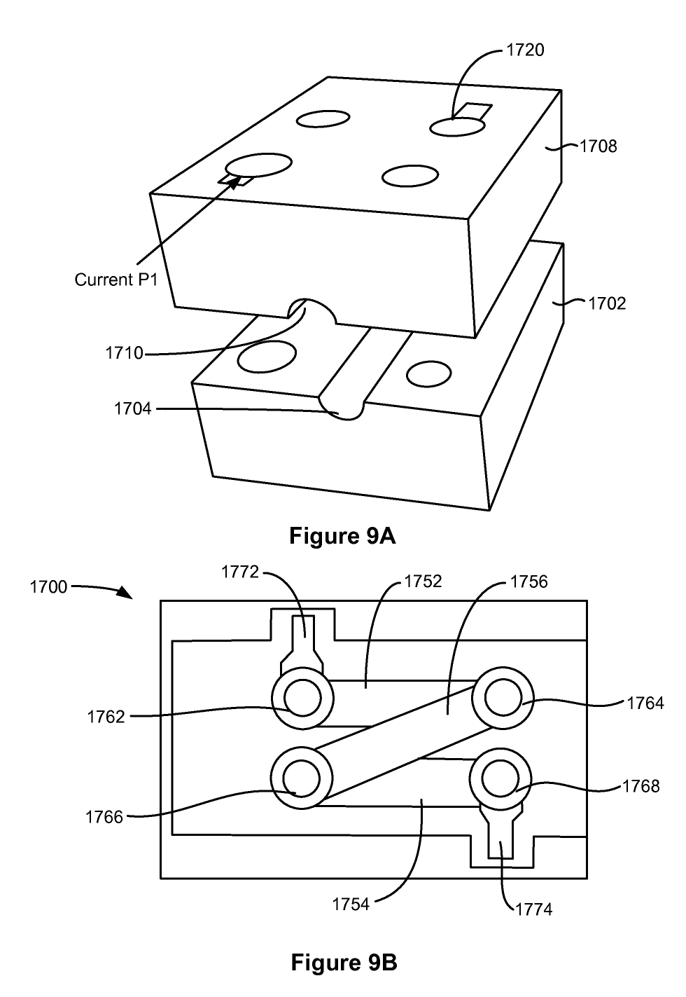

FIGS. 9A and 9B are examples of schematic illustrations of portions of through glass via inductors. FIG. 9A shows an isometric projection of substrates that may be part of an inductor. FIG. 9B shows a top-down schematic illustration of an inductor. The substrates for an inductor 1700 shown in FIG. 9B are clear such that the vias and metal traces on a bottom surface of the inductor 1700 are visible.

Turning first to FIG. 9A, FIG. 9A shows a bottom glass substrate 1702 including a concave recess 1704 and a top glass substrate 1708 including a concave recess 1710. When the bottom glass substrate 1702 is attached to the top glass substrate 1708, the two substrates form a composite substrate defining a cavity. As shown in FIG. 9A, in some implementations, the cavity may be open on the ends of the cavity. The bottom glass substrate 1702 and the top glass substrate 1708 also include four vias, one via which is a via 1720.

FIG. 9B shows a top-down schematic illustration of an inductor 1700 fabricated from the bottom glass substrate 1702 and the top glass substrate 1708 shown in FIG. 9A. The inductor 1700 is a 1.5 turn inductor. The inductor 1700 includes two metal traces 1752 and 1754 on a bottom surface of the inductor 1700. One metal trace 1756 is on a top surface of the inductor 1700. The inductor 1700 further includes vias 1762, 1764, 1766 and 1768 filled with the metal layer. In some implementations, the metal layer does not completely fill the vias 1762, 1764, 1766 and 1768. The bottom metal trace 1752 connects the metal in the vias 1762 and 1764. The top metal trace 1756 connects the metal in the vias 1764 and 1766. The bottom metal trace 1754 connects the metal in the vias 1766 and 1768. Lead 1772 on the top surface of the inductor 1700 is in contact with the metal in the via 1762. Lead 1774 on the top surface of the inductor 1700 is in contact with the metal in the via 1768. Not shown in FIG. 9B is a cavity. The vias and the metal traces of the inductor 1700 may bound the cavity, surround the cavity, or define borders with respect to the cavity (not shown) of the inductor 1700, forming an air core inductor.

The manufacturing process 1500 shown in FIG. 7 may be used to fabricate a through glass via inductor having a number of different configurations. For example, an inductor having any number of turns, such as a half turn, 1 turn, 10 turns, 10.5 turns, 25 turns and 50 turns, may be fabricated with the manufacturing process 1500.

The manufacturing process 1500 may be modified, in some implementations. For example, in some implementations, the vias may be formed in each of the bottom glass substrate and the top glass substrate before the substrates are attached to one another. With this process, the vias may be aligned before attaching the bottom glass substrate to the top glass substrate.

In some implementations, a concave recess may be formed in either the bottom glass substrate or the top glass substrate, but not in both the bottom glass substrate and the top glass substrate. In some implementations, other substrate materials may be used in an inductor, including ceramic substrates or a substrate including a printed circuit board.

In some implementations, the process 1500 may include additional process operations. For example, in some implementations, the process 1500 includes depositing a dielectric adhesion layer on the composite substrate, including the surfaces defining the vias, before depositing the metal layer. A dielectric adhesion layer may improve the adhesion of the metal layer to the glass substrate. In some implementations, a dielectric adhesion layer may be deposited with an ALD process.

In some implementations, the manufacturing process 1500 may include additional process operations to form a magnetic core in the cavity of the through glass via inductor. Thus, an inductor may include a magnetic core disposed in the cavity instead of having an air core. In some implementations, the length of the magnetic core may extend beyond the turns (as defined by the metal layer) of the inductor. In some other implementations, the length of the magnetic core may be within the turns (as defined by the metal layer) of the inductor. In some implementations, a magnetic core may increase the inductance of a through glass via inductor.

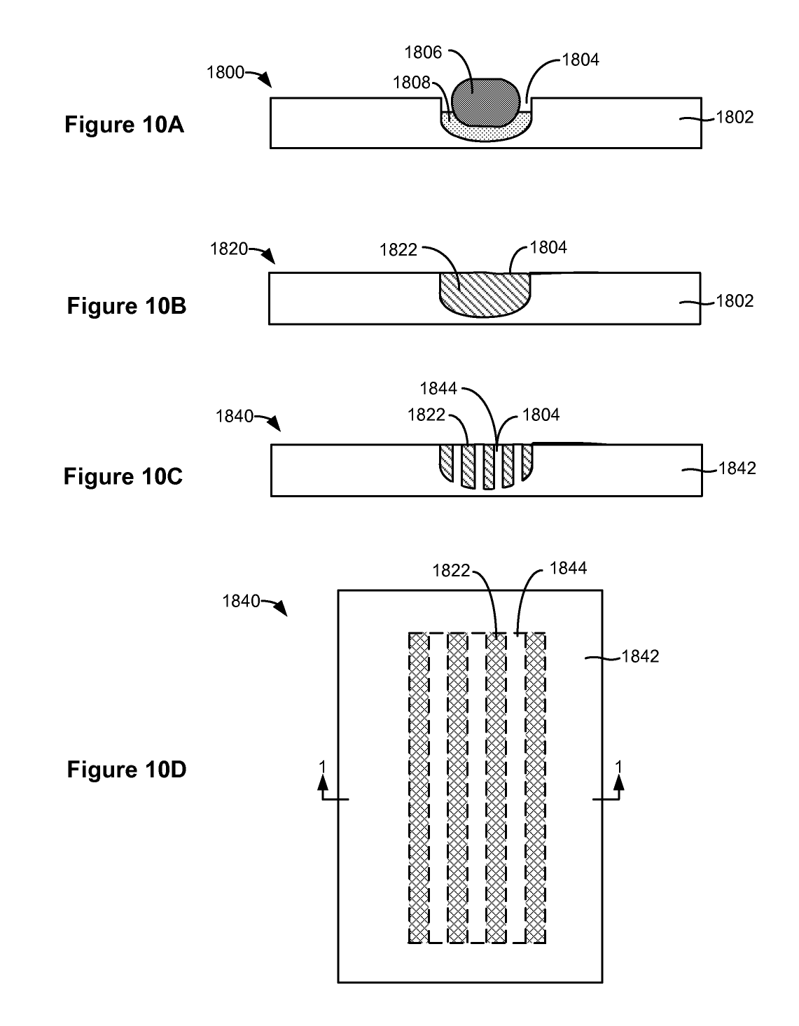

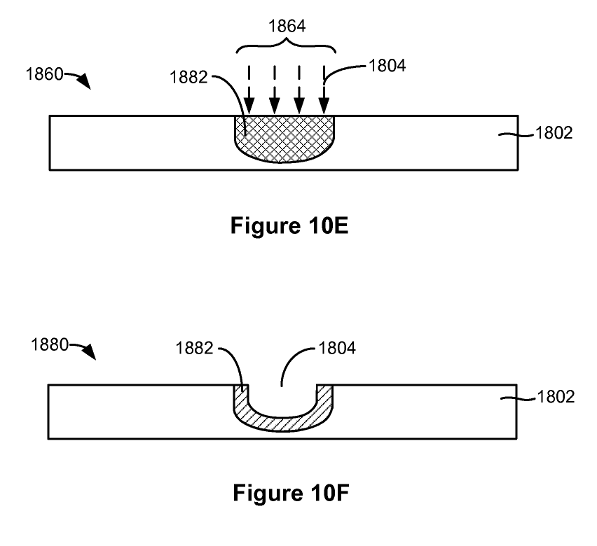

FIGS. 10A-10E are examples of schematic illustrations of different manufacturing process for forming a magnetic core for a through glass via inductor. In some implementations, the magnetic core can be made as big as the cavity in the through glass via inductor. For example, in some implementations, the magnetic core may substantially fill the entire cavity. In some implementations, the magnetic core may have a cross-sectional dimension of a few hundred microns to a few of millimeters. For example, when the cavity is shaped like a cylinder, the diameter of the magnetic core may be about 100 microns to a few millimeters.

In some implementations, the process 1500 may include attaching a magnetic core to the concave recess of one of the bottom glass substrate or the top glass substrate before attaching the bottom glass substrate to the top glass substrate in operation 1504. The magnetic core may be a discrete component including a ferromagnetic material or a ferrimagnetic material. Such materials include Fe, Ni, Co, alloys of Fe, Ni or Co and ferrites, for example. In some implementations, the magnetic core may be bonded to the concave recess of the glass substrate with an adhesive, such as an epoxy.

FIG. 10A shows an example of a cross-sectional schematic illustration of a partially fabricated inductor 1800. The inductor 1800 includes a bottom glass substrate 1802 including a concave recess 1804. Disposed in the concave recess 1804 is a magnetic core 1806, which is attached to the bottom glass substrate 1802 with an adhesive 1808.

In some implementations, the process 1500 may include placing or depositing a material including a bulk ferromagnetic or ferrimagnetic material, or a polymer and particles of a ferromagnetic material or a ferrimagnetic material in the concave recess of at least one of the bottom glass substrate, the top glass substrate, and both the bottom glass substrate and the top glass substrate before attaching the bottom glass substrate to the top glass substrate in operation 1504. Placing the bulk material may include a pick and place or fluidic self-assembly (FSA) process. Depositing the material including the polymer and the particles may include a spin-on process, for example. In some implementations, the particle size of the particles may be few nanometers to tens of microns or larger. In some implementations, the polymer may include an epoxy. In some implementations, a planarization process may be performed to aid in achieving a surface of the material that is coplanar with a surface of the substrate. The polymer may be cured with, for example, heat or ultraviolet light. In some other implementations, the bulk material is a bulk material that has been previously sintered.

FIG. 10B shows an example of a cross-sectional schematic illustration of a partially fabricated inductor 1820. The inductor 1820 includes a bottom glass substrate 1802 including a concave recess 1804. Disposed in the concave recess is a material 1822 including a polymer and particles of a ferromagnetic material or a ferrimagnetic material.

In some implementations, operation 1502 in the process 1500 may form a concave recess in a glass substrate, with sections of substrate protruding into the concave recess. The sections of the substrate may include any of a number of different designs, including a honeycomb structure of the substrate, ridges of the substrate, or an egg carton type pattern of the substrate. For example, the sections may include about one to ten ridges, with the ridges having a width of about 10 microns to 30 microns, or about 20 microns. The sections protruding into the concave recess may be part of the bottom glass substrate, the top glass substrate, or both.

The process 1500 then may further include depositing a material including a polymer and particles of a ferromagnetic material or a ferrimagnetic material in the concave recess of at least one of the bottom glass substrate, the top glass substrate, and both the bottom glass substrate and the top glass substrate before attaching the bottom glass substrate to the top glass substrate in operation 1504. Depositing the material including the polymer and the particles may include a spin-on process, for example. In some implementations, a planarization process may be performed to aid in achieving a surface of the material that is coplanar with a surface of the substrate. The polymer may be cured with, for example, heat or ultraviolet light.

FIGS. 10C and 10D show examples of schematic illustrations of a partially fabricated inductor 1840. FIG. 10C shows an example of a cross-sectional schematic illustration of the inductor 1840 through line 1-1 in the corresponding top-down schematic illustration shown in FIG. 10D. The inductor 1840 includes a bottom glass substrate 1842 including a concave recess 1804. The concave recess 1804 includes ridges 1844 of the bottom glass substrate 1842 protruding into the concave recess 1804. Disposed in the concave recess is a material 1822 including a polymer and particles of a ferromagnetic material or a ferrimagnetic material. As shown, the sections 1844 of the bottom glass substrate 1842 protrude into the magnetic core made up of the polymer and the particles of the ferromagnetic material or the ferrimagnetic material. Thus, laminations of the magnetic core and the substrate are formed. In some implementations, the sections of the substrate protruding into the magnetic core may reduce eddy current losses in the inductor.

In some other implementations, forming a magnetic core having a composite-type structure that includes sections of the substrate may include forming an array of holes or other features instead of forming a cavity recess in the bottom glass substrate, the top glass substrate, or both the bottom glass substrate and the top glass substrate. A material including the polymer and the particles of the magnetic material may be deposited in the holes.

In some implementations, the process 1500 may include depositing a material including particles of a ferromagnetic material or a ferrimagnetic material in the concave recess of at least one of the bottom glass substrate, the top glass substrate, and both the bottom glass substrate and the top glass substrate before attaching the bottom glass substrate to the top glass substrate in operation 1504. In some implementations, the particle size of the particles may be a few nanometers to tens of microns or larger. The particles may then be sintered using a localized heating technique. For example, the particles may be sintered using electromagnetic radiation, including laser light or microwaves, or inductive heating.

FIG. 10E shows an example of a cross-sectional schematic illustration of a partially fabricated inductor 1860. The inductor 1860 includes a bottom glass substrate 1802 including a concave recess 1804. Disposed in the concave recess 1804 is a material 1862 including particles of a ferromagnetic material or a ferrimagnetic material. As shown, electromagnetic radiation 1864 may be used to locally heat the particles and thereby to sinter them.

In some implementations, the process 1500 may include electroplating a ferromagnetic material or a ferrimagnetic material in the concave recess of at least one of the bottom glass substrate, the top glass substrate, and both the bottom glass substrate and the top glass substrate before attaching the bottom glass substrate to the top glass substrate in operation 1504. In some implementations, a seed layer may first be deposited onto a surface of the concave recess. In some implementations, the seed layer may be deposited using a CVD process, an ALD process, or an electroless plating process. Then, the ferromagnetic material or the ferrimagnetic material may be plated onto the seed layer using an electroplating process or an electroless plating process.

FIG. 10F shows an example of a cross-sectional schematic illustration of a partially fabricated inductor 1880. The inductor 1880 includes a bottom glass substrate 1802 including a concave recess 1804. Disposed in the concave recess 1804 is a ferromagnetic material or a ferrimagnetic material 1882 that has been plated.

In some implementations, a ferromagnetic material or a ferrimagnetic material may be plated, then a dielectric layer deposited onto the ferromagnetic material or the ferrimagnetic material, and then additional ferromagnetic material or ferrimagnetic material may be plated. Additional dielectric deposition operations and plating operations may be performed to form a laminated magnetic core; that is, a magnetic core having alternating layers of dielectric material and magnetic material. In some implementations, the laminated magnetic core may reduce eddy current losses in the inductor.

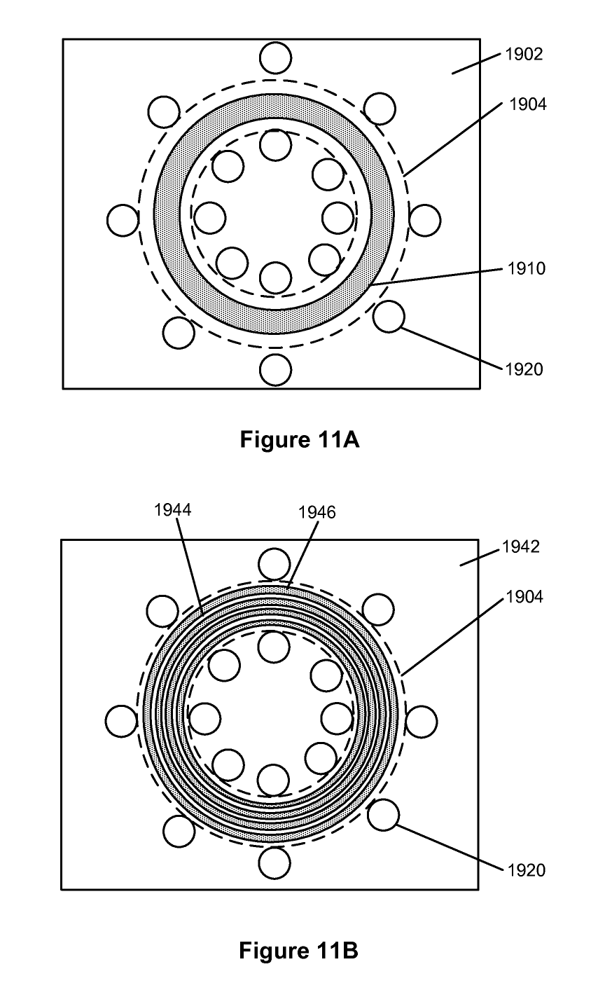

FIGS. 8A-8E, 9A, 9B and 10A-10F are examples of schematic illustrations of through glass via inductors having a solenoid configuration. In some implementations, a through glass via inductor may have a toroidal configuration. FIGS. 11A and 11B are examples of top-down schematic illustrations of bottom glass substrates of through glass via inductors having a toroidal configuration. Turning first to FIG. 11A, a bottom glass substrate 1902 includes a circular shaped concave recess 1904. The concave recess 1904 may have an inner diameter of about 100 microns to a few millimeters and an outer diameter of about 500 microns to 10 mm. In some implementations, the concave recess 1904 may have a magnetic core 1910 disposed in it. The magnetic core 1910 may be any of the magnetic cores described above with respect to FIGS. 10A-10F. The bottom glass substrate 1902 further defines at least two vias, one via which is a via 1920. In some implementations, the vias may have a cross-sectional dimension of about 30 microns to 400 microns. For example, when the vias are cylindrical, the vias may have a diameter of about 30 microns to 500 microns.

FIG. 11B shows a top-down schematic illustration of a bottom glass substrate 1942 including a circular shaped concave recess 1904. The bottom glass substrate 1942 further defines at least two vias, one via which is a via 1920. The concave recess includes ridges 1944 of the bottom glass substrate 1942 protruding into the concave recess 1904. Disposed in the concave recess is a material 1946 including a polymer and particles of a ferromagnetic material or a ferrimagnetic material. The ridges 1944 of the bottom glass substrate 1942 protrude into the magnetic core made up of the polymer and the particles of the ferromagnetic material or the ferrimagnetic material. In some implementations, the ridges 1944 of the bottom glass substrate 1942 protruding into the magnetic core may reduce eddy current losses in the inductor.

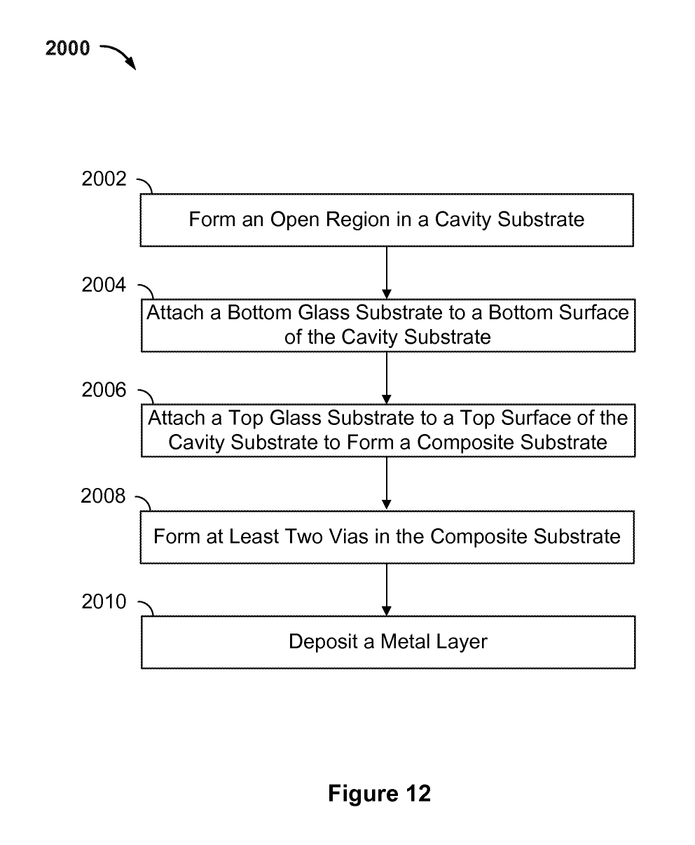

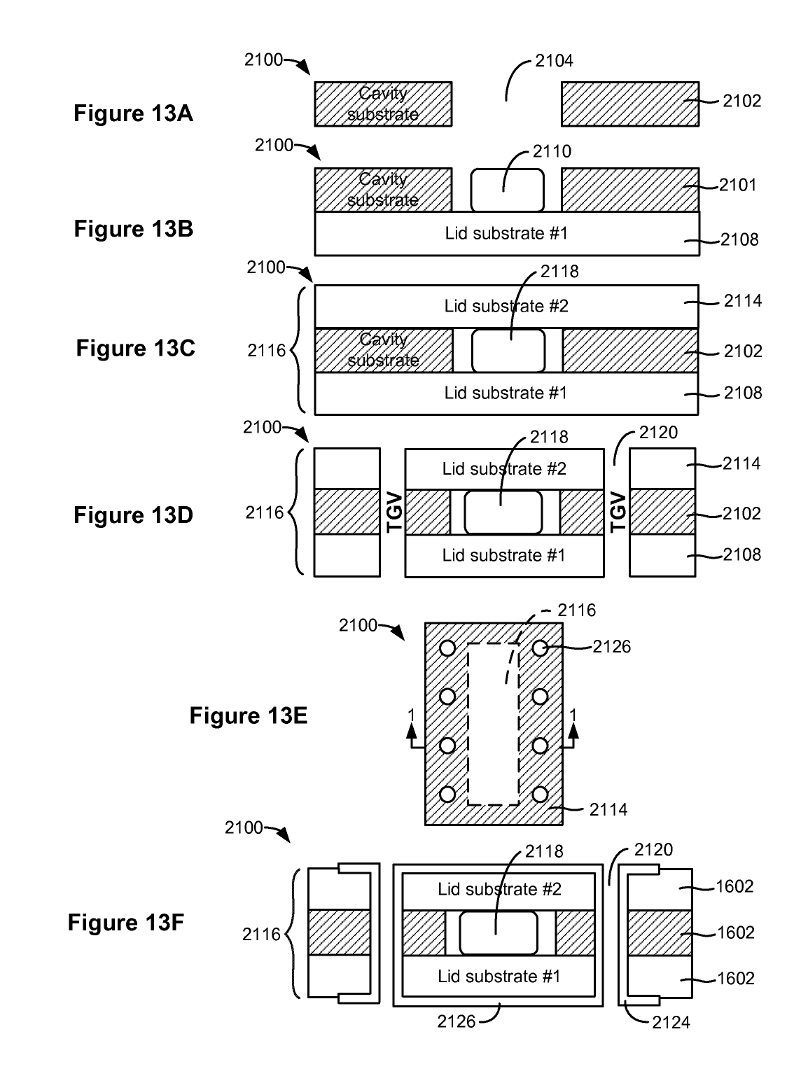

Another implementation of a manufacturing process for a through glass via inductor including three substrates, accompanied by top-down and cross-sectional schematic illustrations of an inductor at various stages in the manufacturing process, is set forth below with respect to FIGS. 12 and 13A-13F. FIG. 12 is an example of a flow diagram illustrating a manufacturing process for a through glass via inductor including three substrates. FIGS. 13A-13F are examples of schematic illustrations of a through glass via inductor including three substrates at various stages in the manufacturing process. In some implementations, a process 2000 shown in FIG. 12 may include similar process operations as the process 1500 shown in FIG. 7. Implementations of the process 2000 use three substrates, however, while implementations of the process 1500 use two substrates. Further, in some implementations, an inductor fabricated with the process 2000 shown in FIG. 12 may be similar to an inductor fabricated with the process 1500 shown in FIG. 7.

In the process 2000 shown in FIG. 12, patterning techniques, including masking as well as etching processes, may be used to define the shapes of the different components of an inductor. At block 2002 of the process 2000, an open region is formed in a cavity substrate. In some implementations, the cavity substrate may include a display glass, a borosilicate glass, or a photoimageable glass. Different processes, including laser ablation processes, sandblasting processes, etching processes, or photoimageable glass processing techniques may be used to form the open region in the cavity substrate, depending on the glass of the cavity substrate. In some other implementations, the cavity substrate may include a polymer or a ceramic. Different processes, including laser ablation and sandblasting, may be used to form the open region in the cavity substrate, depending on the polymer or the ceramic of the cavity substrate.

FIG. 13A shows an example of a cross-sectional schematic illustration of the partially fabricated inductor at this point (such as up through block 2002) in the process 2000. An inductor 2100 includes a cavity substrate 2102 including an open region 2104. In some implementations, the cavity substrate 2102 may be about 100 microns to 1 mm thick, or about 500 microns thick.

Returning to FIG. 12, at block 2004 a bottom glass substrate is attached to a bottom surface of the cavity substrate. In some implementations, the bottom glass substrate may be a borosilicate glass, a display glass, or a photoimageable glass. Different techniques may be used to attach the cavity substrate to the bottom glass substrate, depending on the material of the cavity substrate. In some implementations, when the cavity substrate is a glass, a polymer, or a ceramic, the bottom glass substrate and the cavity substrate may be attached to one another with an adhesive. In some implementations, when the cavity substrate is a glass, the bottom glass substrate and the cavity substrate may be attached to one another with a glass frit bond ring, a metal bond ring, a fusion bond, or an anodic bond.

FIG. 13B shows an example of a cross-sectional schematic illustration of the partially fabricated inductor 2100 at this point (such as up through block 2004) in the process 2000. The inductor 2100 includes the cavity substrate 2102 attached to a bottom glass substrate 2108. The cavity substrate 2102 and the bottom glass substrate 2108 define a recess 2110. In some implementations, the bottom glass substrate 2108 may be about 100 microns to 1 mm thick, or about 500 microns thick.

Returning to FIG. 12, at block 2006 a top glass substrate is attached to a top surface of the cavity substrate. In some implementations, the top glass substrate may be a borosilicate glass, a display glass, or a photoimageable glass. Different techniques may be used to attach the cavity substrate to the top glass substrate, depending on the material of the cavity substrate.

FIG. 13C shows an example of a cross-sectional schematic illustration of the partially fabricated inductor 2100 at this point (such as up through block 2006) in the process 2000. The inductor 2100 includes the cavity substrate 2102 attached to the bottom glass substrate 2108 and to a top glass substrate 2114, forming a composite substrate 2116. The cavity substrate 2102, the bottom glass substrate 2108, and the top glass substrate 2114 forming the composite substrate 2116 define a cavity 2118 in the composite substrate 2116. In some implementations, the top glass substrate 2114 may be about 100 microns to 1 mm thick, or about 500 microns thick. The cavity 2118 has dimensions that depend on the size of the open region formed in the cavity substrate 2102 at block 2002 and the thickness of the cavity substrate 2102. For example, the thickness of the cavity 2118 may be about 100 microns to 1 mm, and the width of the cavity 2118 also may be about 100 microns to 1 mm.

Returning to FIG. 12, at block 2008 at least two vias are formed in the composite substrate. As mentioned above, in some implementations, upper and/or lower surfaces of the composite substrate may be coated with a TGP before forming the vias at block 2008, as described in greater detail below with respect to FIG. 16G. Different process, depending on the material of the cavity substrate and the glasses of the bottom glass substrate and the top glass substrate may be used to form the at least two vias in the composite substrate. For example, when the composite substrate includes a display glass, a borosilicate glass, a polymer, or a ceramic, a laser ablation process, a sandblasting process, or an etching process may be used to form the at least two vias. When the composite substrate includes photoimageable glasses, including the cavity substrate being a photoimageable glass, the at least two vias may be formed by exposing the composite substrate where the at least two vias are to be formed to ultraviolet light, exposing the composite substrate to an elevated temperature, and etching the at least two vias with an acid.

FIGS. 13D and 13E show examples of schematic illustrations of the partially fabricated inductor 2100 at this point (such as up through block 2008) in the process 2000. FIG. 13D shows an example of a cross-sectional schematic illustration of the inductor through line 1-1 in the top-down schematic illustration shown in FIG. 13E. Further, FIG. 13E shows the top glass substrate 2114 and an outline indicating the position of the cavity 2118. The inductor 2100 includes the cavity substrate 2102 attached to the bottom glass substrate 2108 and to the top glass substrate 2114, forming the composite substrate 2116. The composite substrate 2116 defines a cavity 2118. The composite substrate 2116 further defines at least two vias, one via which is a via 2120. In some implementations, the vias may have a cross-sectional dimension of about 30 microns to 500 microns. For example, when the vias are cylindrical, the vias may have a diameter of about 30 microns to 500 microns.

Returning to FIG. 12, at block 2010 a metal layer is deposited. The deposited metal layer at least partially fills the vias and forms traces connecting the vias. For example, when two vias are present, a trace may connect the metal of a first via with the metal of a second via. The vias and the traces may bound the cavity, surround the cavity, or define borders with respect to the cavity.

In some implementations, a dry film mask may be used to define the regions of the composite substrate onto which the metal layer is deposited. In some implementations, the dry film mask may be of a photo-sensitive polymer. In some implementations, the metal layer may be deposited using a PVD process or a CVD process. In some other implementations, the metal layer may be deposited using a plating process, including depositing a seed layer over surfaces of the composite substrate and depositing the metal layer using a plating process, for example. The plating process may be an electroless plating process or an electroplating process.

In some implementations, when the metal layer is deposited using a plating process, a photoresist may be used to define the portions of a seed layer onto which the metal will be plated. After plating the metal, the seed layer remaining on the surfaces of the composite substrate onto which the metal was not plated may be removed. For example, the seed layer may be removed with an etching process.

FIG. 13F shows an example of a cross-sectional schematic illustration of the inductor 2100 at this point (such as up through block 2010) in the process 2000. The inductor 2100 includes the cavity substrate 2102 attached to the bottom glass substrate 2108 and to the top glass substrate 2114, forming the composite substrate 2116. The composite substrate 2116 defines the cavity 2118. The composite substrate 2116 further defines at least two vias, one via which is the via 2120. Metal layer 2124 is disposed on the composite substrate 2116, at least partially filling the vias and forming a trace 2126 connecting the metal of different vias. In some implementations, the metal layer 2124 may include Cu, a Cu alloy, Ni, a Ni alloy, Au, or Al. In some implementations, the metal layer 2124 may be about 0.5 microns to 30 microns thick. In some implementations, the vias and the traces may define borders with respect to the cavity 2118. As shown in FIG. 13F, the metal layer 2124 may not substantially fill the vias. In other some implementations, however, the metal layer may substantially fill the vias.

The manufacturing process 2000 shown in FIG. 12 may be used to fabricate a through glass via inductor, as described above. In some implementations, the process 2000 may include additional process operations. In some implementations, the process 2000 may include the additional process operation of depositing a dielectric adhesion layer on the surfaces of the composite substrate, including the surfaces defining the vias, before depositing the metal layer. A dielectric adhesion layer may improve the adhesion of the metal layer to the composite substrate.

As noted above, implementations of the process 2000 use three substrates. In some implementations, a cavity formed with three substrates in the process 2000 may be enclosed on all sides. This may aid in liquid handling issues when working with wet processing techniques and other tool handling issues. In some other implementations, a cavity formed with the three substrates in the process 2000 may be open on the two ends of the cavity. In some implementations, the thickness of the cavity may be controlled by a height of the cavity substrate. This may aid in the manufacturing process 2000, for example. Further, an inductor having any number of turns, such as a half turn, 1 turn, 10 turns, 10.5 turns, 25 turns and 50 turns may be fabricated with the manufacturing process 2000.

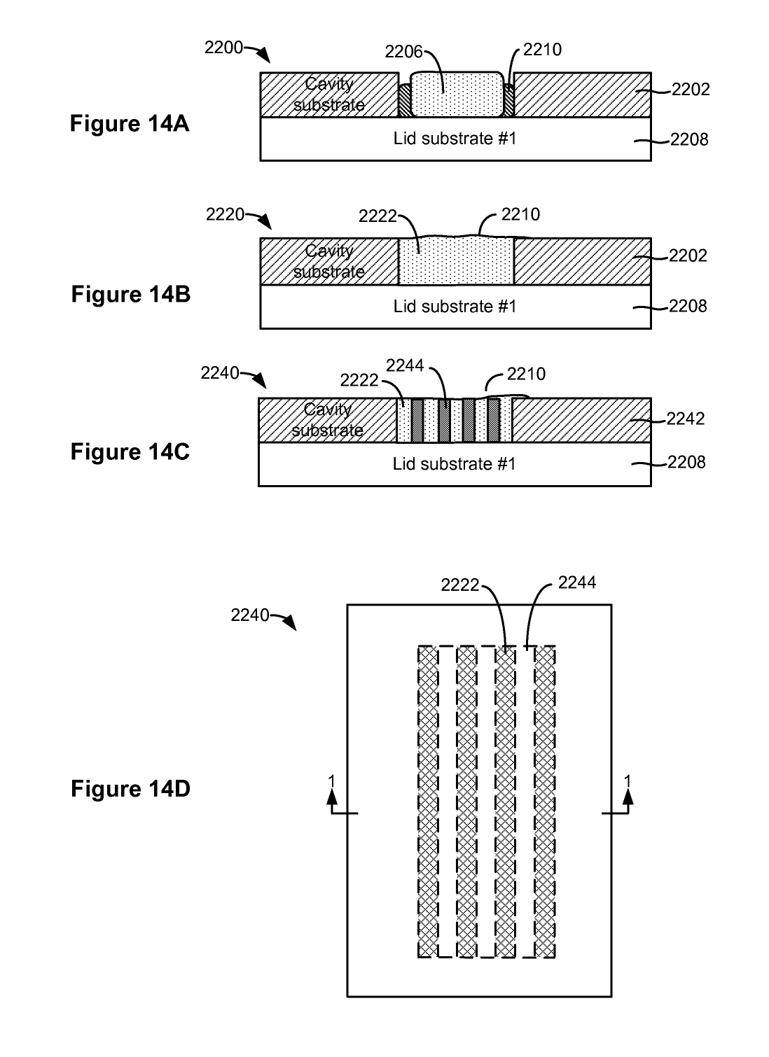

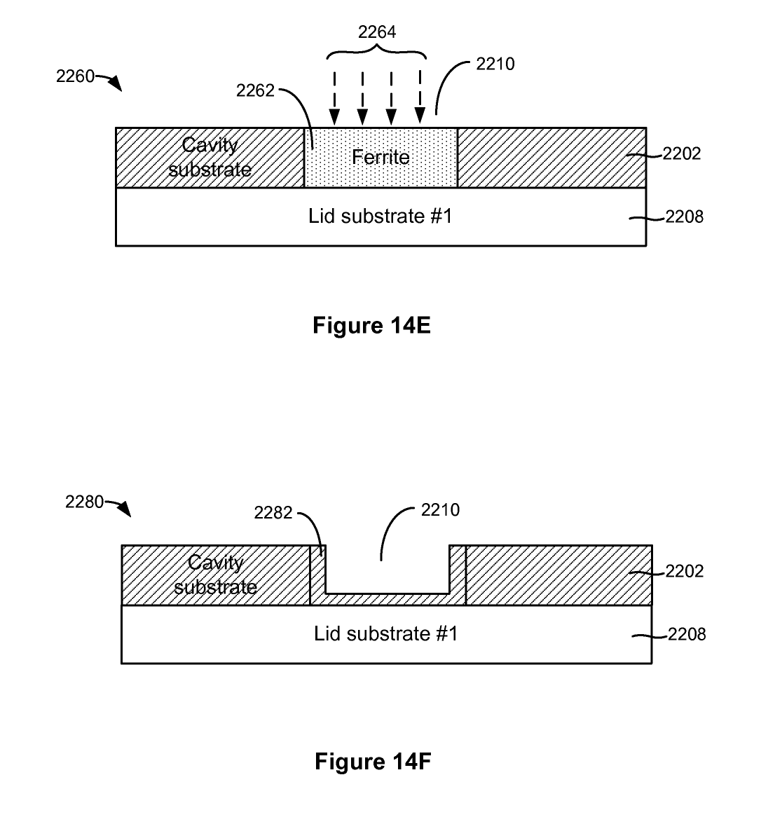

In some implementations, the process 2000 may include forming a magnetic core, as described above with respect to FIGS. 10A-10F. FIGS. 14A-14F are examples of schematic illustrations of different manufacturing process for forming a magnetic core for a through glass via inductor. In some implementations, the magnetic core can be made as large as the cavity in the through glass via inductor. For example, in some implementations, the magnetic core may substantially fill the entire cavity. In some implementations, the magnetic core may have a cross-sectional dimension of a few hundred microns to a couple of millimeters. In some implementations, the length of the magnetic core may extend beyond the turns (as defined by the metal layer) of the inductor. In some other implementations, the length of the magnetic core may be within the turns (as defined by the metal layer) of the inductor.

In some implementations, the process 2000 may include attaching a magnetic core to the recess formed after the cavity substrate is attached to the bottom glass substrate in operation 2004. The magnetic core may be a discrete component including a ferromagnetic material or a ferrimagnetic material. Such materials include Fe, Ni, Co, alloys of Ni, Fe or Co, and ferrites, for example. In some implementations, the magnetic core may be bonded to the recess with an adhesive, such as an epoxy.

FIG. 14A shows an example of a cross-sectional schematic illustration of a partially fabricated inductor 2200. The inductor 2200 includes a cavity substrate 2202 attached to a bottom glass substrate 2208 defining a recess 2210. Disposed in the recess 2210 is a magnetic core 2206, which is attached to the cavity substrate 2202 and the bottom glass substrate 2208 with an adhesive 2212.

In some implementations, the process 2000 may include depositing a material including a polymer and particles of a ferromagnetic material or a ferrimagnetic material in the recess formed after the cavity substrate is attached to the bottom glass substrate in operation 2004. Depositing the material including the polymer and the particles may include a spin-on process, for example. In some implementations, the particle size of the particles may be few nanometers to tens of microns or larger. In some implementations, the polymer may include an epoxy. In some implementations, a planarization process may be performed to aid in achieving a surface of the material that is coplanar with a surface of the cavity substrate. The polymer may be cured with, for example, heat or ultraviolet light.

FIG. 14B shows an example of a cross-sectional schematic illustration of a partially fabricated inductor 2220. The inductor 2220 includes a cavity substrate 2202 attached to a bottom glass substrate 2208 defining a recess 2210. Disposed in the recess 2210 is a material 2222 including a polymer and particles of a ferromagnetic material or a ferrimagnetic material.

In some implementations, the operation 2002 in the process 2000 may form an open region in the cavity substrate including sections of the cavity substrate in the open region. The sections of the cavity substrate may include any of a number of different designs, including a honeycomb structure of the cavity substrate or ridges of the cavity substrate. For example, the sections may include about one to ten ridges, with the ridges having a width of about 10 microns to 30 microns, or about 20 microns.

The process 2000 then further may include depositing a material including a polymer and particles of a ferromagnetic material or a ferrimagnetic material in the recess formed after the cavity substrate is attached to the bottom glass substrate in operation 2004. Depositing the material including the polymer and the particles may include a spin-on process, for example. In some implementations, a planarization process may be performed to aid in achieving a surface of the material that is coplanar with a surface of the cavity substrate. The polymer may be cured with, for example, heat or ultraviolet light.

FIGS. 14C and 14D show examples of schematic illustrations of a partially fabricated inductor 2240. FIG. 14C shows an example of a cross-sectional schematic illustration of the inductor 2240 through line 1-1 in the top-down schematic illustration shown in FIG. 14D. The inductor 2240 includes a cavity substrate 2242 attached to a bottom glass substrate 2208 defining a recess 2210. The cavity substrate 2242 includes ridges 2244 of the cavity substrate 2242 in the open region of the cavity substrate 2242. Disposed in the recess 2210 is a material 2222 including a polymer and particles of a ferromagnetic material or a ferrimagnetic material. Thus, laminations of the magnetic core and the cavity substrate are formed. In some implementations, the sections of the cavity substrate protruding into the magnetic core may reduce eddy current losses in the inductor.

In some implementations, the process 2000 may include depositing a material including particles of a ferromagnetic material or a ferrimagnetic material in the recess formed after the cavity substrate is attached to the bottom glass substrate in operation 2004. In some implementations, the particle size of the particles may be a few nanometers to tens of microns. The particles may then be sintered using a localized heating technique. For example, the particles may be sintered using electromagnetic radiation, including laser light or microwaves.

FIG. 14E shows an example of a cross-sectional schematic illustration of a partially fabricated inductor 2260. The inductor 2260 includes a cavity substrate 2242 attached to a bottom glass substrate 2208 defining a recess 2210. Disposed in the recess 2210 is a material 2262 including particles of a ferromagnetic material or a ferrimagnetic material. As shown, electromagnetic radiation 2264 may be used to heat the particles and to sinter them.

In some implementations, the process 2000 may include electroplating a ferromagnetic material or a ferrimagnetic material in the recess formed after the cavity substrate is attached to the bottom glass substrate in operation 2004. In some implementations, a seed layer may first be deposited onto surfaces of the recess. In some implementations, the seed layer may be deposited using a CVD process, an ALD process, or an electroless plating process. Then, the ferromagnetic material or the ferrimagnetic material may be plated onto the seed layer.

FIG. 14F shows an example of a cross-sectional schematic illustration of a partially fabricated inductor 2280. The inductor 2280 includes a cavity substrate 2202 attached to a bottom glass substrate 2208 defining a recess 2210. Disposed in the recess 2210 is a ferromagnetic material or a ferrimagnetic material 2282 that has been plated.

In some implementations, a ferromagnetic material or a ferrimagnetic material may be plated, then a dielectric layer deposited onto the ferromagnetic material or the ferrimagnetic material, and then additional ferromagnetic material or ferrimagnetic material may be plated. Additional dielectric deposition operations and plating operations may be performed to form a laminated magnetic core.

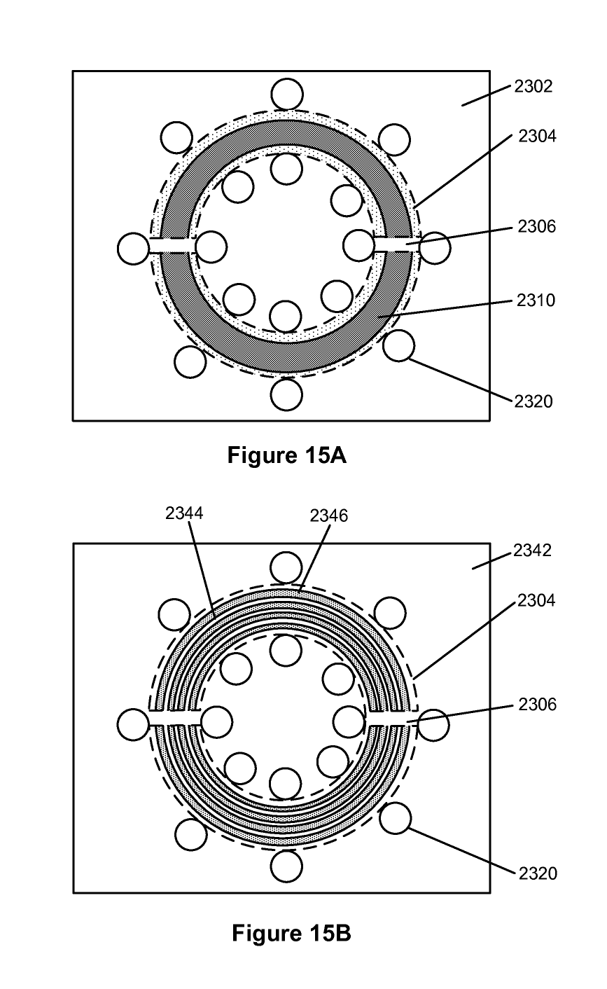

FIGS. 13A-13F and 14A-14F are examples of schematic illustration of through glass via inductors having a solenoid configuration. In some implementations, a through glass via inductor may have a toroidal configuration. FIGS. 15A and 15B are examples of top-down schematic illustrations of cavity substrates having attached bottom glass substrates of through glass via inductors having a toroidal configuration. Turning first to FIG. 15A, a cavity substrate 2302 that has been attached to a bottom glass substrate defines a circular shaped recess 2304. One or more tabs 2306 support a central portion of the cavity substrate 2302. The recess 2304 may have an inner diameter of about 100 microns to a few millimeters and an outer diameter of about 500 microns to 10 mm. In some implementations, the recess 2304 may have a magnetic core 2310 disposed in it. The magnetic core 2310 may be any of the magnetic cores described above with respect to FIGS. 14A-14F. The cavity substrate 2302 and the bottom glass substrate further define at least two vias, one via which is a via 2320. In some implementations, the vias may have a cross-sectional dimension of about 30 microns to 500 microns. For example, when the vias are cylindrical, the vias may have a diameter of about 30 microns to 500 microns.

FIG. 15B shows a top-down schematic illustration of a cavity substrate 2342 attached to a bottom glass substrate defining a circular shaped recess 2304. The cavity substrate 2342 and the bottom glass substrate further define at least two vias, one via which is a via 2320. The cavity substrate 2342 includes ridges 2344 of the cavity substrate 2342 in the recess 2304. One or more tabs 2306 support a central portion of the cavity substrate 2342 and the ridges 2344. Disposed in the recess 2304 is a material 2346 including a polymer and particles of the ferromagnetic material or the ferrimagnetic material. The ridges 2344 of the cavity substrate 2342 protrude into the magnetic core made up of the polymer and particles of a ferromagnetic material or a ferrimagnetic material. In some implementations, the ridges 2344 of the cavity substrate 2342 protruding into the magnetic core may reduce eddy current losses in the inductor.

Any of the through glass via inductors disclosed herein, for instance, fabricated as described above with reference to FIG. 1A, 1B, 4, 7, or 12, can have a toroidal configuration as an alternative to a solenoidal configuration, as mentioned above with reference to FIGS. 11A, 11B, 15A, and 15B. For instance, returning to process 100A of FIG. 1A, the resulting inductor 1000 at block 108, as shown in FIG. 2C, can have a toroidal shape.

FIGS. 16A and 16B are examples of top-down schematic illustrations of toroidal through glass via inductors fabricated using any of the processes disclosed herein. In implementations where the inductor includes one or more embedded substrates and/or a magnetic core, such items have been omitted from FIGS. 16A and 16B for purposes of illustration. FIG. 16A shows an 8-turn inductor 2400A, while FIG. 16B shows a 12-turn inductor 2400B. The turns are sequential and form a single continuous conductive path around the generally toroidal configuration, beginning at an input terminal 2402 and terminating at an output terminal 2403. The input and output terminals 2402 and 2403 can be reversed, depending on the desired implementation.

In both FIGS. 16A and 16B, a respective turn of the inductor includes an upper metal trace 2404 and a lower metal trace 2408. In this example, the metal traces are elongated and of generally consistent width from one end to the other, as illustrated. The turn also includes metal 2412 disposed in a first via connecting overlaying ends of the metal traces 2404 and 2408, and metal 2416 disposed in a second via connecting overlaying ends of the lower metal trace 2408 and the upper metal trace of the next turn of the inductor. Regardless of whether the toroidal inductor includes 4 turns, 6 turns, 8, turns, 12 turns, 16 turns, 32 turns, etc., the turns are arranged in a general toroid shape as illustrated in the examples of FIGS. 16A and 16B. When the toroidal inductor is fabricated using a substrate, as described in the various examples above, the toroidal inductor can thus be situated in a plane substantially parallel to the substrate, for instance, parallel to the X-Y plane illustrated in FIGS. 2A-2C.

By way of example only, when the inductors 2400A and 2400B are fabricated according to process 100A of FIG. 1A, the inductor 2400A can have a trace width 2420a of about 230 microns, an inductance (L) of about 11.96 nanohenries (nH) at 1 gigahertz (GHz), and a quality factor of about 174 at 1 GHz; the inductor 2400B can have a trace width 2420b of about 400 microns, an L of about 15.4 nH at 1 GHz, and a quality factor of about 328 at 1 GHz. In another example, the trace width 2420b of the inductor 2400B is about 230 microns, the L of inductor 2400B is about 16.87 at 1 GHz, and the quality factor of inductor 2400B is about 350 at 1 GHz.

FIG. 16C is an example of a top-down schematic illustration of a toroidal through glass via inductor having tapered metal traces and fabricated using any of the processes disclosed herein. In this example, upper metal traces 2504 have a tapered shape in a general direction from an outer side 2512 towards an inner side 2516 of the toroidal inductor 2500 along an X-Y plane. The tapered shapes of the traces allow more traces and thus more windings to be included in a given area. The tapered shape of each metal trace is defined by a wider portion 2508 proximate the outer side 2512 and a narrower portion 2510 proximate the inner side 2516. One or both of the upper metal traces and lower metal traces (not shown) can have the tapered shape, depending on the desired implementation. Some examples of toroidal inductors with such tapered windings can have a lower resistance than inductors constructed without tapered windings, and the tapered windings can be used to tune the coil capacitance of the toroidal inductor.

FIGS. 16D-16F are examples of simplified top-down schematic illustrations of general shapes of toroidal through glass via inductors fabricated using any of the processes disclosed herein. The toroidal inductor can have a circular shape 2600 as shown in FIG. 16D, a racetrack shape 2604 as shown in FIG. 16E, or an elliptical shape 2608 as shown in FIG. 16F. Various combinations of such annular shapes are possible. The examples of FIGS. 16D-16F represent several of many possible variations with different degrees of arced contours. Also, some toroidal inductors constructed according to the disclosed implementations can have angular contours, such as a top-down rectangular or square shape.

FIG. 16G is an example of a cross-sectional schematic illustration of a through glass via inductor including one or more thermal ground planes (TGPs) fabricated using any of the processes disclosed herein. In implementations where the inductor 2700 includes more than one substrate, FIG. 16G shows a simplified representation of such substrates in the form of substrate 2704. In implementations where the inductor includes a magnetic core, any such core has been omitted from FIG. 16G for purposes of illustration. The inductor 2700 has been fabricated with an upper thermal ground plane (TGP) 2708 deposited on an upper surface 2712 of the substrate 2704. In some instances, the inductor 2700 is fabricated to also or alternatively include a lower TGP 2716 deposited on a lower surface 2720 of the substrate 2704. Any cavity or via 2724 formed in the substrate 2704 is also formed in the thermal ground planes 2708 and 2716.

In some examples, incorporating one or more TGPs may lower the effective thermal resistance of the substrate and provide enhanced heat-dissipation capabilities. In FIG. 16G, in some implementations, the TGPs 2708 and 2716 are formed of an electrically non-conductive material such as AN. AN can be desirable in some instances to provide high thermal conductivity, a satisfactory coefficient of thermal expansion (CTE) match to glass substrates, and a low dielectric loss tangent. In some other implementations, the TGPs are formed of diamond-like carbon (DLC) or graphene.

In some implementations, a transformer is realized using a pair of toroidal inductors fabricated using the techniques disclosed above. FIGS. 16H and 16I are examples of top-down schematic illustrations of four-terminal toroidal through glass via transformers fabricated using any of the processes disclosed herein. FIG. 16H shows two opposing partial toroidal coils 2804 and 2808, each occupying a respective annular portion of the toroidal transformer 2800. A first set of turns 2812 defines the first coil 2804 having an input terminal 2816 and an output terminal 2820. A second set of turns 2824 defines a second coil 2808 having an input terminal 2828 and an output terminal 2832. The first coil 2804 is spatially separated from the second coil 2808 by gaps 2836 and 2840.

FIG. 16I shows two overlaying full toroidal coils 2904 and 2908, both occupying the same general annular area of the toroidal transformer 2900. A first set of turns 2912 defines the first coil 2904 having an input terminal 2916 and an output terminal 2920. A second set of turns 2924 defines a second coil 2908 having an input terminal 2928 and an output terminal 2932. In FIG. 16I, because the same coils 2904 and 2908 occupy the same general area of the toroidal transformer 2900, sections of metal of the first coil 2904 overlay sections of metal of the second coil 2908 or vice versa, as illustrated in FIG. 16I.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

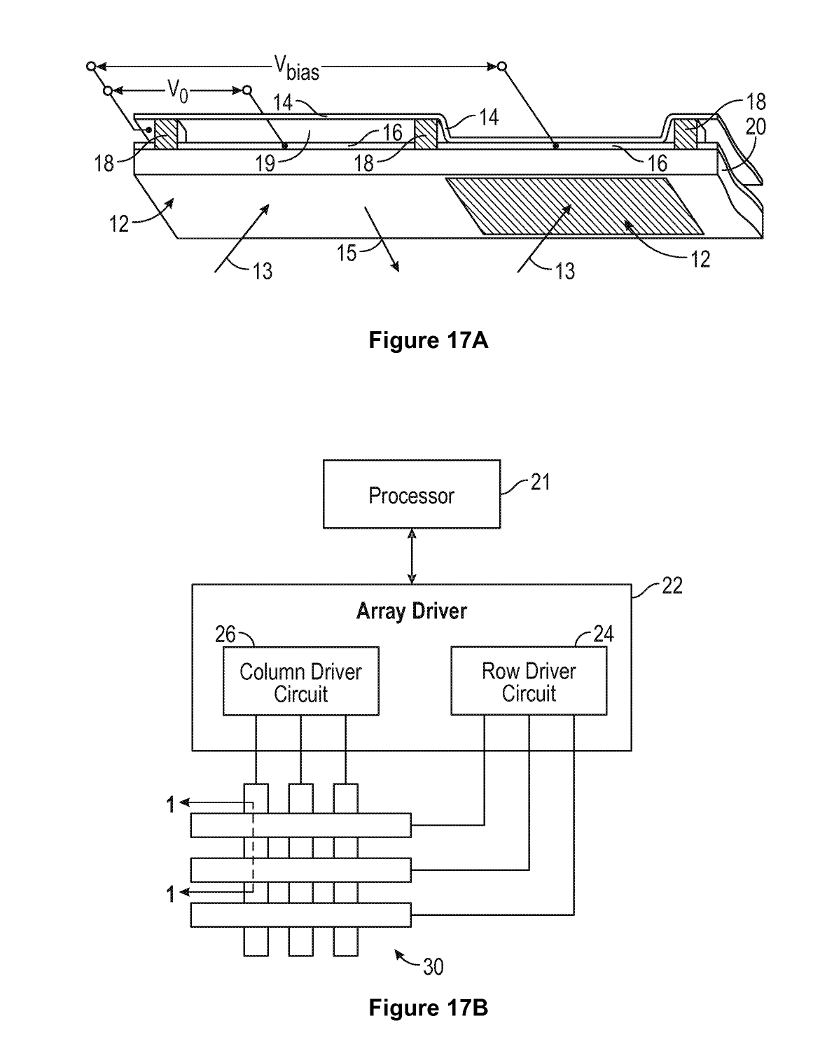

FIG. 17A is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 17A includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 17A, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 17A and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 17A, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 17A. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 17B is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 17A is shown by the lines 1-1 in FIG. 17B. Although FIG. 17B illustrates a 3×3 array of IMOD display elements for the sake of clarity, the display array 30 may contain a very large number of IMOD display elements, and may have a different number of IMOD display elements in rows than in columns, and vice versa.

In some implementations, the packaging of an EMS component or device, such as an IMOD-based display, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

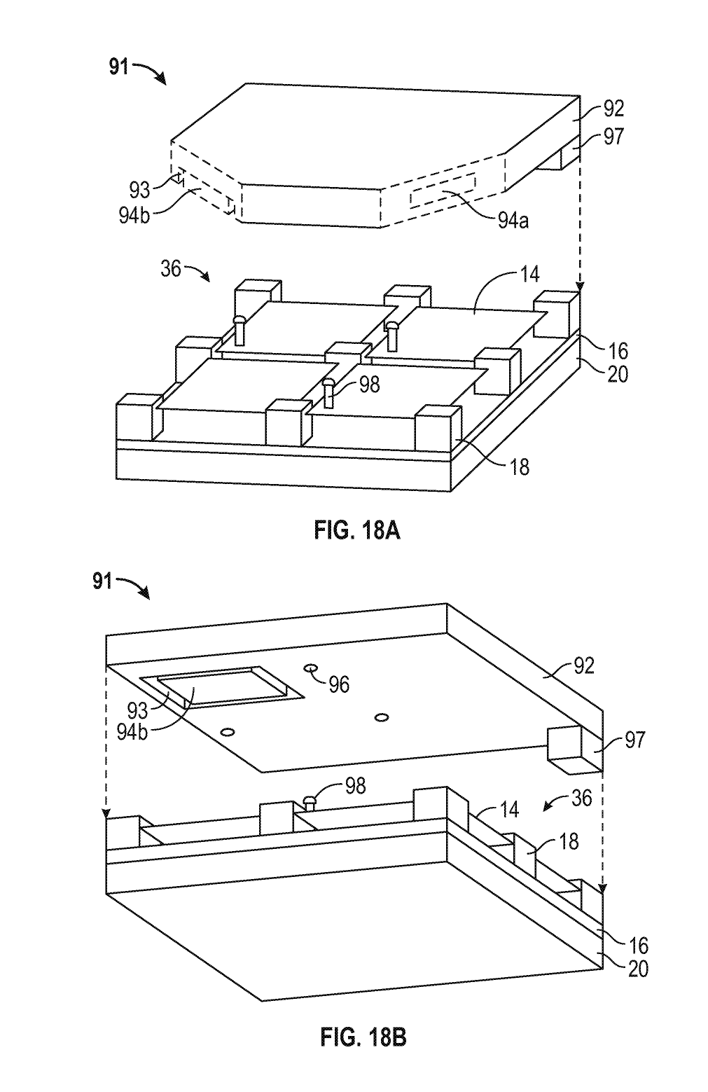

FIGS. 18A and 18B are schematic exploded partial perspective views of a portion of an EMS package 91 including an array 36 of EMS elements and a backplate 92. FIG. 18A is shown with two corners of the backplate 92 cut away to better illustrate certain portions of the backplate 92, while FIG. 18B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 18A and 18B, the backplate 92 can include one or more backplate components 94a and 94b, which can be partially or wholly embedded in the backplate 92. As can be seen in FIG. 18A, backplate component 94a is embedded in the backplate 92. As can be seen in FIGS. 18A and 18B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 18B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 18A and 18B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 18A and 18B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

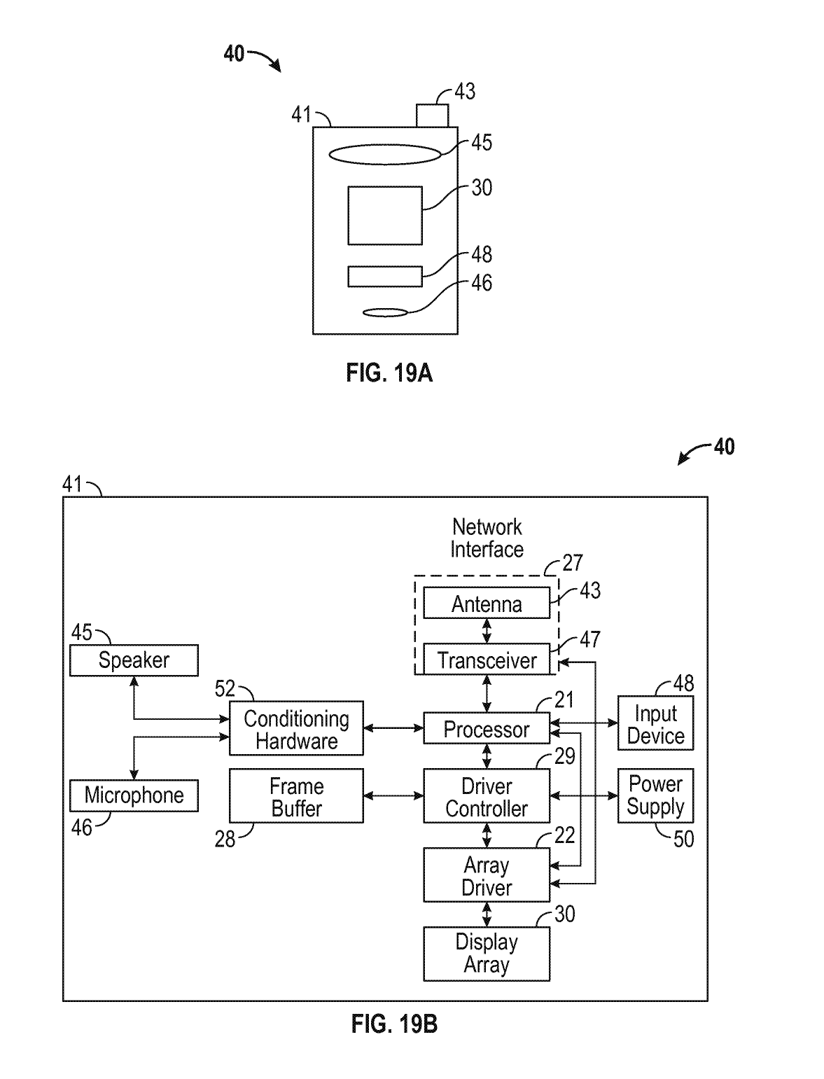

FIGS. 19A and 19B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 19A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 19A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations. As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
a glass substrate having a first surface and a second surface, a cavity being defined in the glass substrate;
at least two metal bars in the cavity, a first end of each metal bar proximate the first surface of the glass substrate and a second end of each metal bar proximate the second surface of the glass substrate; and
a metal trace connecting a first metal bar and a second metal bar.

2. The device of claim 1, further comprising:
a first dielectric layer disposed on the first surface of the glass substrate and a second dielectric layer disposed on the second surface of the glass substrate, wherein the cavity is further defined in the first and the second dielectric layers.

3. The device of claim 2, wherein the metal trace is in contact with the first dielectric layer.

4. The device of claim 1, wherein the glass substrate includes a photoimageable glass substrate.

5. The device of claim 1, wherein the at least two metal bars include at least one of solid metal bars and hollow metal bars.

6. The device of claim 1, further comprising:
a magnetic core disposed in the cavity, the first metal bar, the second metal bar, and the metal trace defining borders with respect to the magnetic core.

7. An apparatus comprising:
the device of claim 1;
a display;
a processor that is configured to communicate with the display, the processor being configured to process image data; and
a memory device that is configured to communicate with the processor.

8. The apparatus of claim 7, further comprising:
a driver circuit configured to send at least one signal to the display; and
a controller configured to send at least a portion of the image data to the driver circuit.

9. The apparatus of claim 7, further comprising:
an image source module configured to send the image data to the processor, wherein the image source module includes at least one of a receiver, transceiver, and transmitter.

10. The apparatus of claim 7, further comprising:
an input device configured to receive input data and to communicate the input data to the processor.

11. The device of claim 1, wherein the metal bars and the metal trace define an inductor having a degree of flexibility corresponding to a variable inductance of the inductor.

12. The device of claim 1, wherein:
the glass substrate is flexible; and
the metal bars and the metal trace define an inductor having a variable inductance corresponding to a degree of strain or displacement of the flexible substrate.

13. The device of claim 12, wherein the inductor is configured as a sensor to provide an output signal at an output terminal responsive to an input, the output signal indicating the degree of strain or displacement of the flexible substrate.

14. Resonator circuitry comprising:
the device of claim 11; and
a capacitor coupled in a circuit with the device of claim 11.

15. The device of claim 1, wherein the metal bars and the metal trace define at least a portion of one of a plurality of metal turns arranged in a toroid to define a toroidal inductor situated in a plane substantially parallel to the glass substrate.

16. The device of claim 15, wherein the metal trace has a tapered shape along the plane, the tapered shape defined by a wider portion proximate an outer side of the toroid and a narrower portion proximate an inner side of the toroid.

17. The device of claim 15, wherein the toroid has one of: a circular shape, an elliptical shape, and a racetrack shape.

18. The device of claim 15, further comprising:
one or more thermal ground planes disposed on one or both surfaces of the glass substrate, wherein the cavity is further defined in the one or more thermal ground planes.

19. The device of claim 18, wherein the one or more thermal ground planes includes one or more of: aluminum nitride (AlN), diamond-like carbon (DLC), and graphene.

20. The device of claim 15, wherein the plurality of metal turns includes: a first set of turns defining a first coil having an input terminal and an output terminal.

21. The device of claim 20, wherein the plurality of metal turns further includes: a second set of turns defining a second coil having an input terminal and an output terminal, the first coil and the second coil defining a transformer.

22. The device of claim 21, wherein at least a portion of the first coil overlays the second coil.

23. The device of claim 21, wherein the first coil is situated in a first portion of the toroid, and the second coil is situated in a second portion of the toroid and spaced apart from the first coil.

24. A method comprising:
forming at least two vias in a glass substrate, the glass substrate including a photoimageable glass, an area of the glass substrate where a cavity is to be formed including the at least two vias;
exposing the glass substrate to an elevated temperature; and
depositing a metal layer, the metal layer at least partially filling a first via and a second via and forming a trace connecting metals of the first via and the second via.

25. The method of claim 24, further comprising:
depositing a dielectric layer on a first side and on a second side of the glass substrate.

26. The method of claim 25, further comprising:
removing a portion of the dielectric layer disposed on the first side of the glass substrate to uncover at least a portion of the area of the glass substrate.

27. The method of claim 24, further comprising:
depositing a thermal ground plane layer on one or more of a first side and a second side of the glass substrate.

28. The method of claim 24, further comprising:
exposing the area of the glass substrate to ultraviolet light; and
etching the area of the glass substrate exposed to the ultraviolet light with an acid.

29. The method of claim 28, wherein forming the at least two vias in the glass substrate includes:
exposing the area of the glass substrate where the at least two vias are to be formed to the ultraviolet light;
exposing the glass substrate to the elevated temperature; and
etching the at least two vias in the glass substrate with the acid.

30. The method of claim 24, wherein forming the at least two vias in the glass substrate includes at least one of: a sandblasting process, a laser ablation process, an ultrasonic drilling process, and an acid etch process.

31. The method of claim 24, wherein depositing the metal layer includes:
depositing a seed layer with at least one of a physical vapor deposition process, a chemical vapor deposition process, an evaporation process, an atomic layer deposition process, and an electroless plating process; and
plating a metal on the seed layer to form the metal layer.

32. The method of claim 24, further comprising:
before depositing the metal layer, depositing a dielectric adhesion layer on the glass substrate, wherein the metal layer is deposited on the dielectric adhesion layer.

33. A method comprising:
forming at least two vias and a channel between the at least two vias in a glass substrate, the glass substrate including a photoimageable glass, an area of the glass substrate where a cavity is to be formed including the at least two vias and the channel;
exposing the glass substrate to an elevated temperature;
forming a first polymer support in a portion of the channel;
forming a magnetic core in the channel, the magnetic core disposed on the first polymer support;
forming a second polymer support in the channel, the second polymer support disposed on the magnetic core; and
depositing a metal layer, the metal layer at least partially filling a first via and a second via and forming a trace connecting metals of the first via and the second via.

34. The method of claim 33, further comprising:
depositing a dielectric layer on a first side and on a second side of the glass substrate.

35. The method of claim 34, further comprising:
removing a portion of the dielectric layer disposed on the first side of the glass substrate to uncover at least a portion of the area of the glass substrate.

36. The method of claim 33, further comprising:
depositing a thermal ground plane layer on one or more of a first side and a second side of the glass substrate.

37. The method of claim 33, further comprising:
exposing the area of the glass substrate to ultraviolet light; and
etching the area of the glass substrate exposed to the ultraviolet light with an acid.

38. The method of claim 37, wherein forming the at least two vias and the channel in the glass substrate includes:
exposing the area of the glass substrate where the at least two vias and the channel are to be formed to the ultraviolet light;
exposing the glass substrate to the elevated temperature; and
etching the at least two vias and the channel in the glass substrate with the acid.

39. The method of claim 33, wherein forming the at least two vias and the channel in the glass substrate includes at least one of: a sandblasting process, a laser ablation process, an ultrasonic drilling process, and an acid etch process.

40. The method of claim 33, wherein depositing the metal layer includes:
depositing a seed layer with at least one of a physical vapor deposition process, a chemical vapor deposition process, an evaporation process, an atomic layer deposition process, and an electroless plating process; and
plating a metal on the seed layer to form the metal layer.

41. The method of claim 33, further comprising:
depositing a dielectric adhesion layer, wherein the metal layer is deposited on the dielectric adhesion layer.

42. The method of claim 33, wherein forming the first polymer support and the second polymer support include:
depositing a polymer material;
removing portions of the polymer material not overlying the channel; and
heating the polymer material such that the polymer material flows into the channel.
